(19) United States
(12) Patent Application Publication
(10) Pub. No.: US 2024/0315016 A1
(43) Pub. Date: Sep. 19, 2024

(54) SEMICONDUCTOR DEVICE AND METHODS FOR MANUFACTURING THE SAME

(71) Applicant: Kioxia Corporation, Tokyo (JP)

(72) Inventors: Seungkeun BAEK, Yokkaichi Mie (JP); Teruhisa SONOHARA, Yokkaichi Mie (JP)

(21) Appl. No.: 18/594,742

(22) Filed: Mar. 4, 2024

(30) Foreign Application Priority Data
Mar. 17, 2023 (JP) 2023-043226

(51) Int. Cl. H10B 41/27; H01L 23/00; H01L 25/18; H10B 43/27; H10B 80/00

(52) U.S. Cl. CPC H10B 41/27; H10B 43/27; H01L 24/05; H01L 24/06; H01L 24/08; H01L 25/18; H01L 2224/05647; H01L 2224/06181; H01L 2224/08145; H01L 2924/1431; H01L 2924/14511; H10B 80/00

(57) ABSTRACT

A semiconductor device includes a stacked film, a plurality of plugs, and a columnar portion. The stacked film includes a plurality of electrodes, which includes a first electrode, and a plurality of first insulating films alternately stacked in a first direction. The plurality of plugs extends through the stacked film in the first direction. The plurality of plugs includes a first plug electrically connected to the first electrode. The columnar portion extends through the stacked film in the first direction. The columnar portion includes a charge storage layer and a semiconductor layer. The first electrode includes a metal layer and the first plug includes a metal layer that is integrally formed with the metal layer of the first electrode and formed of a same material as a material of the metal layer of the first electrode.

### CROSS-REFERENCE TO RELATED APPLICATION

This application is based upon and claims the benefit of priority from Japanese Patent Application No. 2023-043226, filed Mar. 17, 2023, the entire contents of which are incorporated herein by reference.

### FIELD

Embodiments described herein relate generally to a semiconductor device and a method for manufacturing the same.

### BACKGROUND

In three-dimensional semiconductor memories, various problems may occur between electrode layers such as word lines and contact plugs for the electrode layers.

### BRIEF DESCRIPTION OF THE DRAWINGS

FIG. 1 illustrates a cross-sectional view of a structure of a semiconductor device according to a first embodiment.

FIG. 2 illustrates an enlarged cross-sectional view of the structure of the semiconductor device of the first embodiment.

FIGS. 3-4 are cross-sectional view diagrams to explain process steps in a method for manufacturing a semiconductor device of the first embodiment.

FIG. 5 illustrates a cross-sectional view of a structure of a semiconductor device according to a modification of the first embodiment.

FIGS. 6-8 are cross-sectional view diagrams to explain process steps in a method for manufacturing the semiconductor device according to the modification of the first embodiment.

FIGS. 9A and 9B through FIGS. 36A and 36B are cross-sectional view diagrams to explain process steps in the method for manufacturing the semiconductor device of the first embodiment.

FIGS. 37A and 37B are cross-sectional view diagrams for comparing a semiconductor device of a comparative example of the first embodiment with the semiconductor device of the first embodiment.

FIGS. 38A, 38B, 39A, and 39B are cross-sectional view diagrams to explain process steps in a method for manufacturing the semiconductor device of the comparative example of the first embodiment.

FIGS. 40A, 40B, 41A, and 41B are cross-sectional view diagrams to explain process steps in the method for manufacturing the semiconductor device of the first embodiment.

### DETAILED DESCRIPTION

Embodiments provide a semiconductor device and a method for manufacturing the same, capable of implementing suitable electrode layers and plugs.

In general, according to an embodiment, a semiconductor device includes a stacked film, a plurality of plugs, and a columnar portion. The stacked film includes a plurality of electrodes, which includes a first electrode, and a plurality of first insulating films alternately stacked in a first direction. The plurality of plugs extends through the stacked film in the first direction. The plurality of plugs includes a first plug electrically connected to the first electrode. The columnar portion extends through the stacked film in the first direction. The columnar portion includes a charge storage layer and a semiconductor layer. The first electrode includes a metal layer and the first plug includes a metal layer that is integrally formed with the metal layer of the first electrode and formed of a same material as a material of the metal layer of the first electrode.

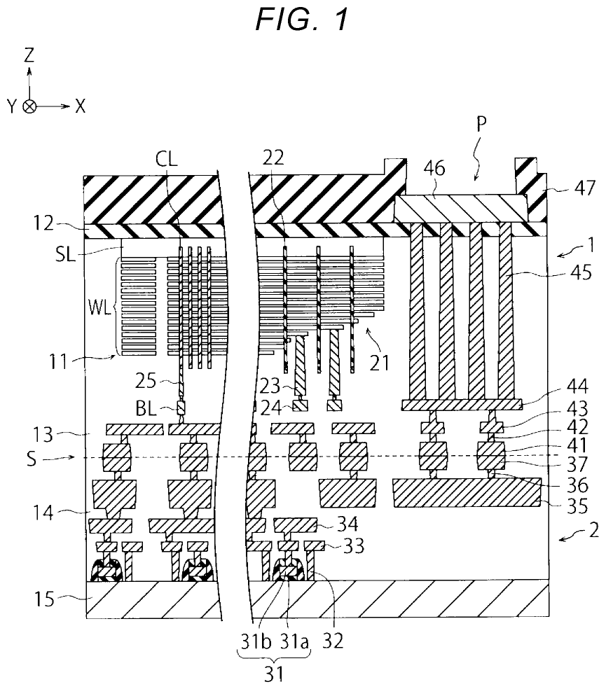

Embodiments of the present disclosure will be described below with reference to the drawings. In FIGS. 1 to 41, the same components are denoted by the same reference numerals, and redundant description will be omitted.

### FIRST EMBODIMENT

FIG. 1 illustrates a cross-sectional view of a structure of a semiconductor device of a first embodiment.

The semiconductor device of the first embodiment includes, for example, a three-dimensional semiconductor memory. The semiconductor device of the first embodiment is manufactured by bonding together an array wafer including an array chip 1 and a circuit wafer including a circuit chip 2, as described below.

The array chip 1 includes a memory cell array 11 including a plurality of memory cells, an insulating film 12 on the memory cell array 11, and an interlayer insulating film 13 below the memory cell array 11. The insulating film 12 is, for example, a SiO₂ film (silicon oxide film). The interlayer insulating film 13 is, for example, a stacked film including the SiO₂ film and another insulating film.

The circuit chip 2 is provided below the array chip 1. The symbol S indicates the bonding surface between the array chip 1 and the circuit chip 2. The circuit chip 2 includes an interlayer insulating film 14 below the interlayer insulating film 13 and a substrate 15 below the interlayer insulating film 14. The interlayer insulating film 14 is, for example, a stacked film including the SiO₂ film and another insulating film. The substrate 15 is, for example, a semiconductor substrate such as the Si (silicon) substrate.

FIG. 1 illustrates the X and Y directions parallel to an upper surface of the substrate 15 and perpendicular to each other, and the Z direction perpendicular to the upper surface of the substrate 15. The X direction, Y direction, and Z direction intersect each other. In this specification, the +Z direction is treated as the upward direction, and the −Z direction is treated as the downward direction. The −Z direction may coincide with the direction of gravity or may not coincide with the direction of gravity. The Z direction is an example of the first direction.

The array chip 1 includes a plurality of word lines WL as the plurality of electrode layers in the memory cell array 11. FIG. 1 illustrates a stepped structure portion 21 in the memory cell array 11 and a plurality of beams 22 provided in the stepped structure portion 21. Each word line WL is electrically connected to a word wiring layer 24 via a contact plug 23. Further details of the contact plug 23 will be described below. Each columnar portion CL passing through the plurality of word lines WL is electrically connected to a bit line BL via a plug 25, and is also electrically connected to a source line SL. The bit lines BL are provided below these word lines WL, and the source lines SL are provided above these word lines WL.

The circuit chip 2 includes a plurality of transistors 31. Each transistor 31 includes a gate insulating film 31a and a gate electrode 31b provided in this order on the substrate 15 and a source diffusion layer (not illustrated) and a drain diffusion layer (not illustrated) provided in the substrate 15. The circuit chip 2 also includes a plurality of contact plugs 32 provided on the gate electrode 31b, the source diffusion layer or the drain diffusion layer of these transistors 31, a wiring layer 33 provided on these contact plugs 32 and including the plurality of wirings, and a wiring layer 34 provided on the wiring layer 33 and including the plurality of wirings.

The circuit chip 2 further includes a wiring layer 35 provided on the wiring layer 34 and including a plurality of wirings, a plurality of via plugs 36 provided on the wiring layer 35, and a plurality of metal pad 37 provided on these via plugs 36. The metal pad 37 is, for example, a metal layer including a Cu (copper) layer. The circuit chip 2 functions as a control circuit (e.g., logic circuit) that controls the operation of the array chip 1. This control circuit is configured with the transistor 31 or the like and is electrically connected to the metal pad 37.

The array chip 1 includes a plurality of metal pads 41 provided on the metal pad 37 and a plurality of via plugs 42 provided on the metal pad 41. In addition, the array chip 1 includes a wiring layer 43 provided on these via plugs 42 and including a plurality of wirings and a wiring layer 44 provided on the wiring layer 43 and including a plurality of wirings. The metal pad 41 is, for example, a metal layer including a Cu layer. The bit line BL mentioned above is provided in the wiring layer 44. Further, the above-mentioned control circuit is electrically connected to the memory cell array 11 via the metal pads 41, 37, and the like and controls the operation of the memory cell array 11 via the metal pads 41, 37, and the like.

The array chip 1 further includes a plurality of via plugs 45 provided on the wiring layer 44, metal pads 46 provided on the via plugs 45 and the insulating film 12, and a passivation insulating film 47 provided on the metal pads 46 and the insulating film 12. The metal pad 46 is, for example, a metal layer including the Cu layer and functions as an external connection pad (e.g., bonding pad) of the semiconductor device of the present embodiment. The passivation insulating film 47 is, for example, a stacked film including the SiO₂ film and the silicon nitride film (SiN film) and has an opening P that exposes the upper surface of the metal pad 46. The metal pad 46 can be connected to the mounting board or other device through the opening P using the bonding wire, the solder ball, the metal bump, or the like.

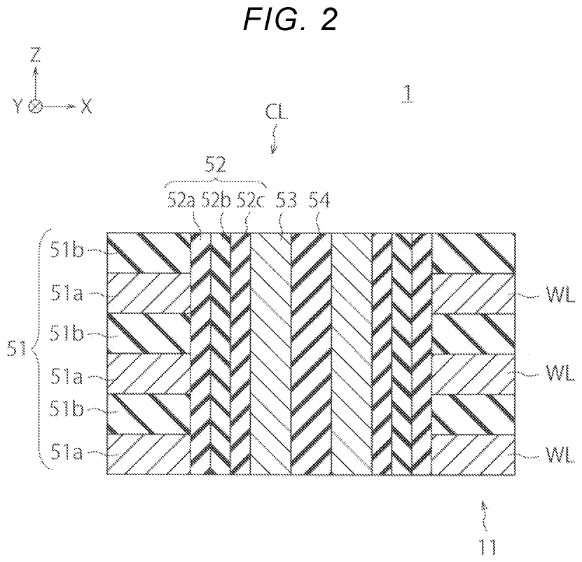

FIG. 2 illustrates an enlarged cross-sectional view of the structure of the semiconductor device of the first embodiment.

FIG. 2 illustrates the memory cell array 11 illustrated in FIG. 1. The memory cell array 11 includes a stacked film 51 including a plurality of electrodes 51a and a plurality of insulating films 51b alternately stacked in the Z direction. These electrodes 51a function, for example, as the above-mentioned word lines WL. Each electrode 51a is, for example, one or more metal layers including a W (tungsten) layer. Each insulating film 51b is, for example, a SiO₂ film. These insulating films 51b are examples of the first insulating films.

FIG. 2 further illustrates one among the plurality of columnar portions CL illustrated in FIG. 1. Each columnar portion CL includes a memory insulating film 52, a channel semiconductor layer 53, and a core insulating film 54 provided in this order on the side surface of the stacked film 51. The memory insulating film 52 includes a block insulating film 52a, a charge storage layer 52b, and a tunnel insulating film 52c provided in this order on the side surface of the stacked film 51. The charge storage layer 52b is, for example, an insulating film such as a SiN film. The charge storage layer 52b may be the semiconductor layer such as the polysilicon layer. The channel semiconductor layer 53 is, for example, a polysilicon layer. The block insulating film 52a, the tunnel insulating film 52c, and the core insulating film 54 are, for example, a SiO₂ films. The tunnel insulating film 52c may be a silicon oxynitride film (SiON film).

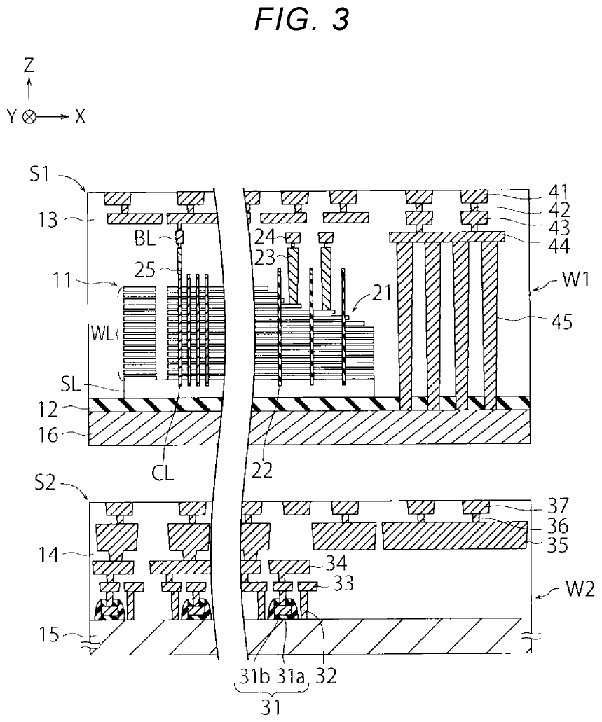

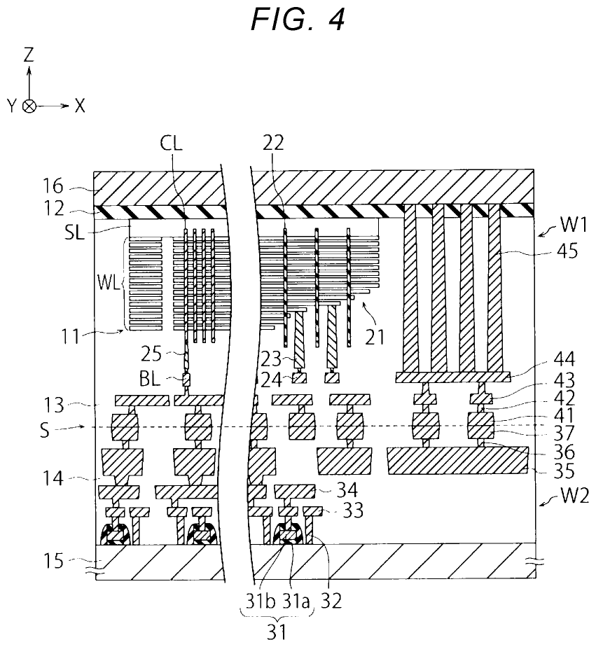

FIGS. 3 and 4 are cross-sectional view diagrams to explain process steps in a method for manufacturing the semiconductor device of the first embodiment.

FIG. 3 illustrates an array wafer W1 including the plurality of array chips 1 and a circuit wafer W2 including the plurality of circuit chips 2. The orientation of the array wafer W1 in FIG. 3 is opposite to the orientation of the array chip 1 in FIG. 1. In the present embodiment, the semiconductor device is manufactured by bonding the array wafer W1 and the circuit wafer W2. FIG. 3 illustrates the array wafer W1 before the orientation is reversed for bonding, and FIG. 1 illustrates the array chip 1 after the orientation is reversed for bonding, and bonding and dicing are performed.

In FIG. 3, a symbol S1 indicates the upper surface of the array wafer W1, and a symbol S2 indicates the upper surface of the circuit wafer W2. The array wafer W1 includes the substrate 16 provided below the insulating film 12. The substrate 16 is, for example, a semiconductor substrate such as a Si substrate.

In the present embodiment, first, as illustrated in FIG. 3, the memory cell array 11, the insulating film 12, the interlayer insulating film 13, the stepped structure portion 21, the metal pad 41, and the like are formed on the substrate 16 of the array wafer W1, and then, the interlayer insulating film 14, the transistor 31, the metal pad 37, and the like are formed on the substrate 15 of the circuit wafer W2. Next, as illustrated in FIG. 4, the array wafer W1 and the circuit wafer W2 are bonded together by mechanical pressure so that the surfaces S1 and S2 face each other. As a result, the interlayer insulating film 13 and the interlayer insulating film 14 are bonded together. Next, the array wafer W1 and the circuit wafer W2 are annealed. Accordingly, the metal pad 41 and the metal pad 37 are bonded. In this manner, the substrate 16 and the substrate 15 are bonded together through the interlayer insulating films 13 and 14.

After that, the substrate 16 is removed by chemical mechanical polishing (CMP), and after the substrate 15 is thinned by the CMP, the array wafer W1 and the circuit wafer W2 are cut into a plurality of chips (dicing). In this manner, the semiconductor device illustrated in FIG. 1 is manufactured. It is noted that the metal pad 46 and the passivation insulating film 47 are formed on the insulating film 12 after the substrate 16 is removed and the substrate 15 is thinned.

It is noted that, although FIG. 1 illustrates the boundary surface between the interlayer insulating film 13 and the interlayer insulating film 14 and the boundary surface between the metal pad 41 and the metal pad 37, these boundary surfaces are generally not observed after the above-mentioned annealing. However, the positions of these boundary surfaces can be estimated by detecting, for example, an inclination of the side surface of the metal pad 41, the inclination of the side surface of the metal pad 37, or the positional deviation between the side surface of the metal pad 41 and the side surface of the metal pad 37.

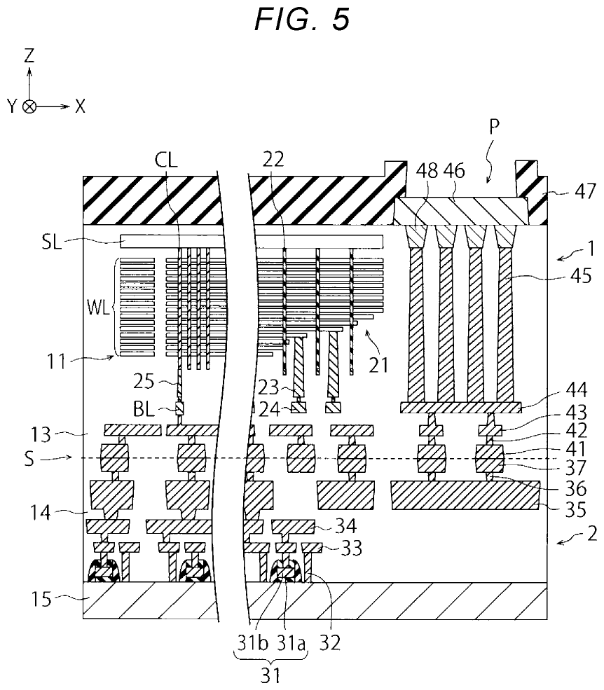

FIG. 5 illustrates a cross-sectional view of a structure of a semiconductor device according to a modification of the first embodiment.

The semiconductor device (FIG. 5) of this modification has the same structure as the semiconductor device (FIG. 1) of the first embodiment. However, while the source lines SL in the first embodiment are formed before the array wafer and the circuit wafer are bonded together, the source lines SL in this modification are formed after the array wafer and the circuit wafer are bonded together.

The semiconductor device of this modification further includes a plurality of via plugs 48 on the respective plurality of via plugs 45. The metal pad 46 of this modification is provided on the via plug 45 via the via plug 48.

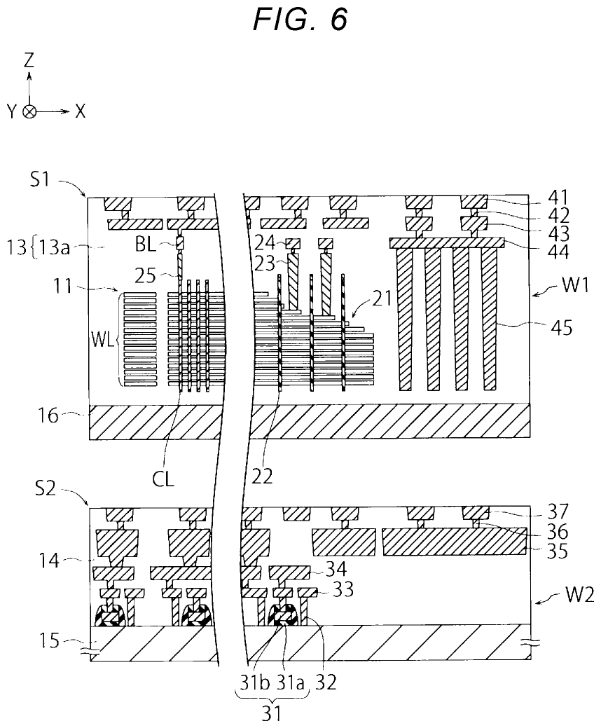

FIGS. 6 to 8 are cross-sectional view diagrams to explain process steps in a method for manufacturing the semiconductor device according to the modification of the first embodiment.

FIG. 6 illustrates the array wafer W1 including the plurality of array chips 1 and the circuit wafer W2 including the plurality of circuit chips 2. For the same reason as in the cases illustrated in FIGS. 1 and 3, the orientation of the array wafer W1 in FIG. 6 is opposite to the orientation of the array chip 1 in FIG. 5.

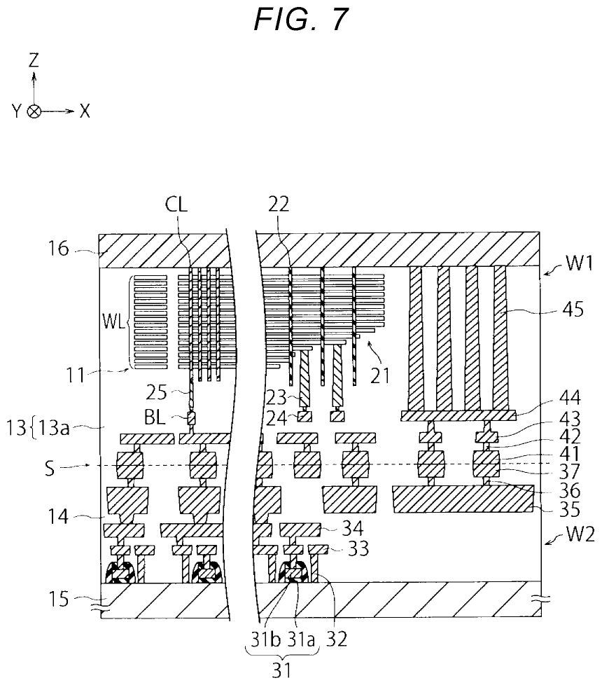

In this modification, first, as illustrated in FIG. 6, the memory cell array 11, an interlayer insulating film 13a (=a portion of the interlayer insulating film 13), the stepped structure portion 21, the metal pad 41, and the like are formed on the substrate 16 of the array wafer W1, and the interlayer insulating film 14, the transistor 31, the metal pad 37, and the like are formed on the substrate 15 of the circuit wafer W2. Next, as illustrated in FIG. 7, the array wafer W1 and the circuit wafer W2 are bonded together by mechanical pressure so that the surfaces S1 and S2 face each other. As a result, the interlayer insulating film 13a and the interlayer insulating film 14 are bonded together. Next, the array wafer W1 and the circuit wafer W2 are annealed. Accordingly, the metal pad 41 and the metal pad 37 are bonded. In this manner, the substrate 16 and the substrate 15 are bonded together through the interlayer insulating films 13a and 14.

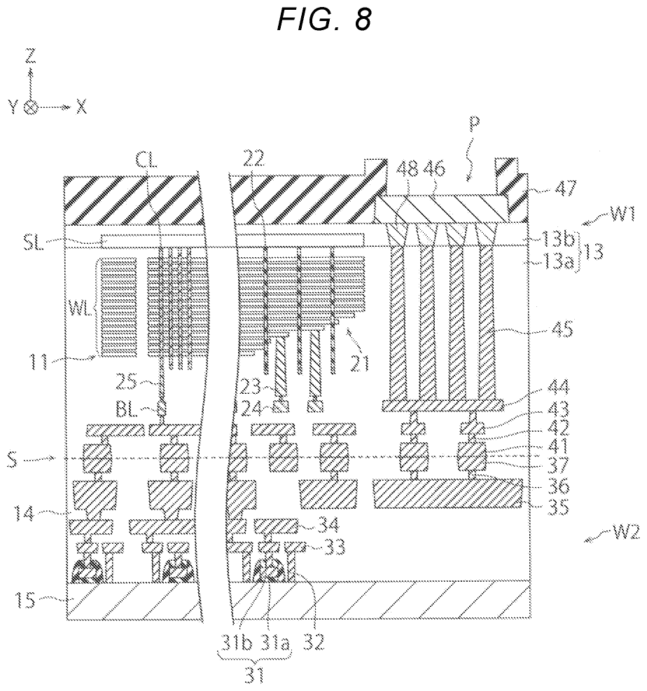

Next, as illustrated in FIG. 8, the substrate 16 is removed by the CMP, and the substrate 15 is thinned by the CMP. As a result, the interlayer insulating film 13a, the columnar portion CL, the beam portion 22, the via plug 45, and the like are exposed. Next, the source line SL is formed on the columnar portion CL and the beam portion 22, and the interlayer insulating film 13b (=the remaining portion of the interlayer insulating film 13) is formed on the interlayer insulating film 13a via the source line SL, and the via plug 48 is formed on the via plug 45 in the interlayer insulating film 13b (FIG. 8). Next, the metal pad 46 is formed on the interlayer insulating film 13b and the via plug 48, and the passivation insulating film 47 is formed on the interlayer insulating film 13b and the metal pad 46 (FIG. 8). After that, the array wafer W1 and the circuit wafer W2 are cut into the plurality of chips. In this manner, the semiconductor device illustrated in FIG. 5 is manufactured.

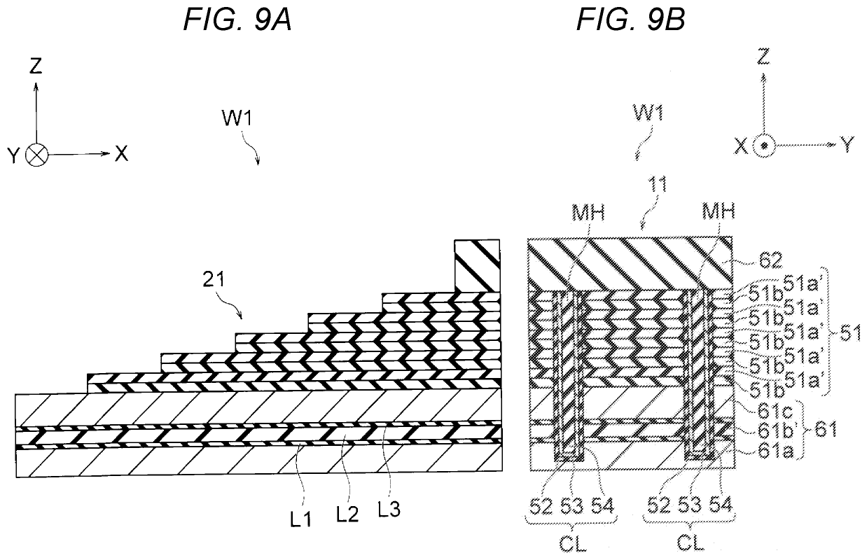

FIGS. 9A to 36B are cross-sectional view diagrams to explain process steps in the method for manufacturing the semiconductor device of the first embodiment. This method corresponds in detail to the method illustrated in FIGS. 3 and 4, but is generally similarly applicable to the methods illustrated in FIGS. 6 to 8.

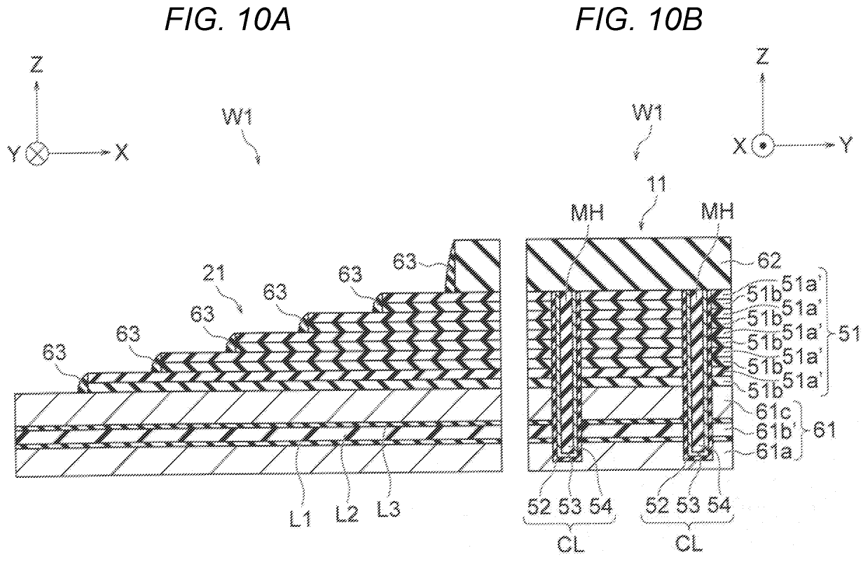

FIG. 9A illustrates the XZ cross section of the semiconductor device of the present embodiment. FIG. 9B illustrates a YZ cross section of the semiconductor device of the present embodiment. This also applies to FIGS. 10A to 36B.

First, the source layer 61 is formed on the substrate 16 (not illustrated) of the array wafer W1 via the insulating film 12 (not illustrated) (FIGS. 9A and 9B). The source layer 61 is formed to include a semiconductor layer 61a, a sacrifice layer 61b′, and a semiconductor layer 61c in this order. The semiconductor layer 61a is, for example, a polysilicon layer. The sacrifice layer 61b′ is, for example, a stacked film including layers L1, L2, and L3 in this order. The layer L1 is, for example, a SiO₂ film. The layer L2 is, for example, a SiN film. The layer L3 is, for example, a SiO₂ film. The semiconductor layer 61c is, for example, a polysilicon layer. The source layer 61 functions as the source line SL described above.

Next, the stacked film 51 is formed on the source layer 61, and a portion of the stacked film 51 is processed into the stepped structure portion 21 (FIGS. 9A and 9B). The stacked film 51 is formed by alternately stacking a plurality of sacrifice layers 51a′ and a plurality of insulating films 51b on the source layer 61. The sacrifice layer 51a′ is an example of the first layer, and the insulating film 51b is an example of the first insulating film. The sacrifice layer 51a′ is, for example, a SiN film. FIG. 9A illustrates, as the example, the stepped structure portion 21 including five steps.

Next, the plurality of memory holes MH extending in the Z direction are formed in the stacked film 51 and the source layer 61 (FIGS. 9A and 9B). Next, the memory insulating film 52, the channel semiconductor layer 53, and the core insulating film 54 are sequentially formed in each memory hole MH (FIGS. 9A and 9B). As a result, the columnar portion CL is formed in each memory hole MH. Next, the interlayer insulating film 62 is formed on the stacked film 51 so as to cover each columnar portion CL (FIGS. 9A and 9B). The interlayer insulating film 62 is a portion of the interlayer insulating film 13 described above. The interlayer insulating film 62 is, for example, a SiO₂ film. In FIGS. 9A and 9B, the memory hole MH and the columnar portion CL pass through the stacked film 51 in the Z direction.

Next, a spacer layer 63 is formed on the side surface of each step of the stepped structure portion 21 (FIGS. 10A and 10B). The spacer layer 63 is, for example, a SiO₂ film. The spacer layer 63 is formed by depositing the SiO₂ film and processing the SiO₂ film by etching back. The spacer layer 63 is also formed on the side surface of the interlayer insulating film 62.

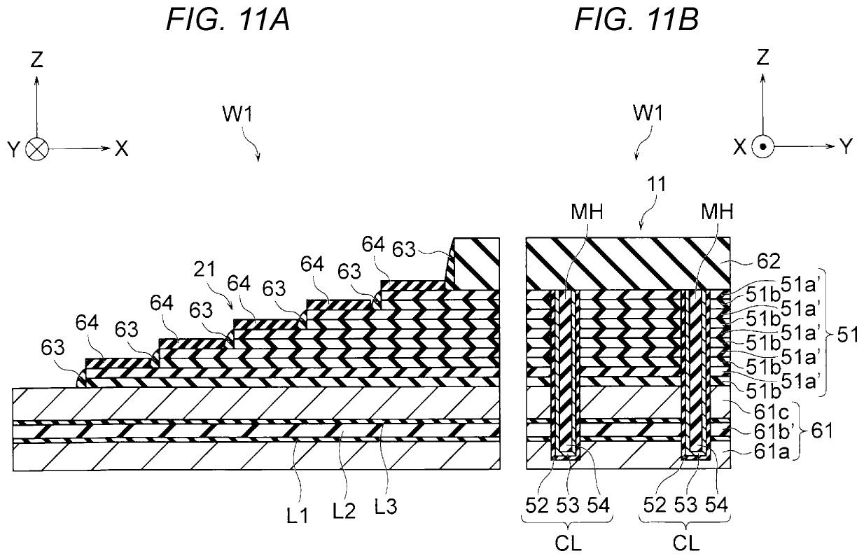

Next, a selective growth layer 64 is formed on the upper surface of each step of the stepped structure portion 21 (FIGS. 11A and 11B). The selective growth layer 64 is, for example, a SiN film. The selective growth layer 64 is formed by selectively growing the selective growth layer 64 from the upper surface of each sacrifice layer 51a′.

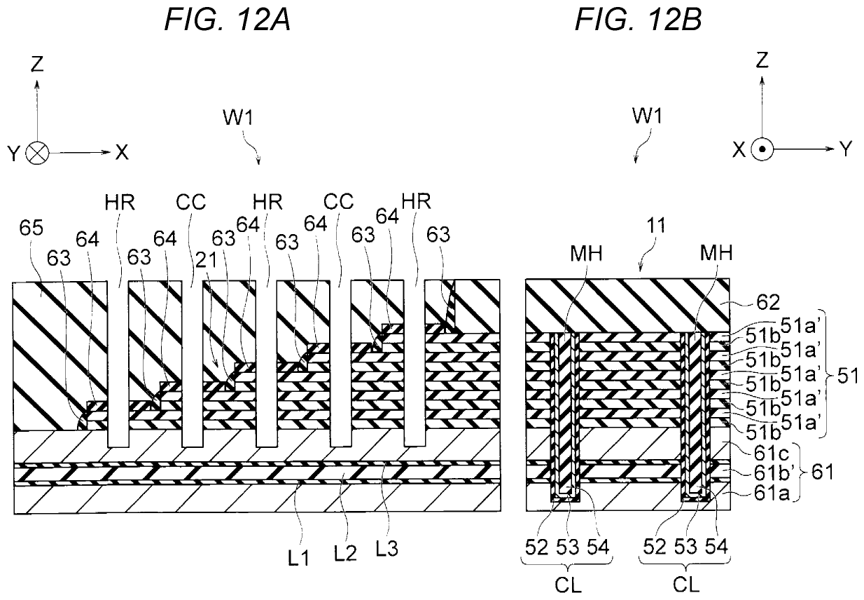

Next, an interlayer insulating film 65 is formed on the stepped structure portion 21, and a plurality of contact holes CC and a plurality of beam holes HR are formed simultaneously in the interlayer insulating film 65 and the stepped structure portion lithography and RIE (Reactive Ion Etching) (FIGS. 12A and 12B). These contact holes CC and beam holes HR are formed to pass through the corresponding selective growth layer 64 and reach the source layer 61. FIG. 12A illustrates two contact holes CC and three beam holes HR as an example. Each contact hole CC is an example of a hole. The interlayer insulating film 65 is a portion of the interlayer insulating film 13 described above. The interlayer insulating film 65 is, for example, a SiO₂ film.

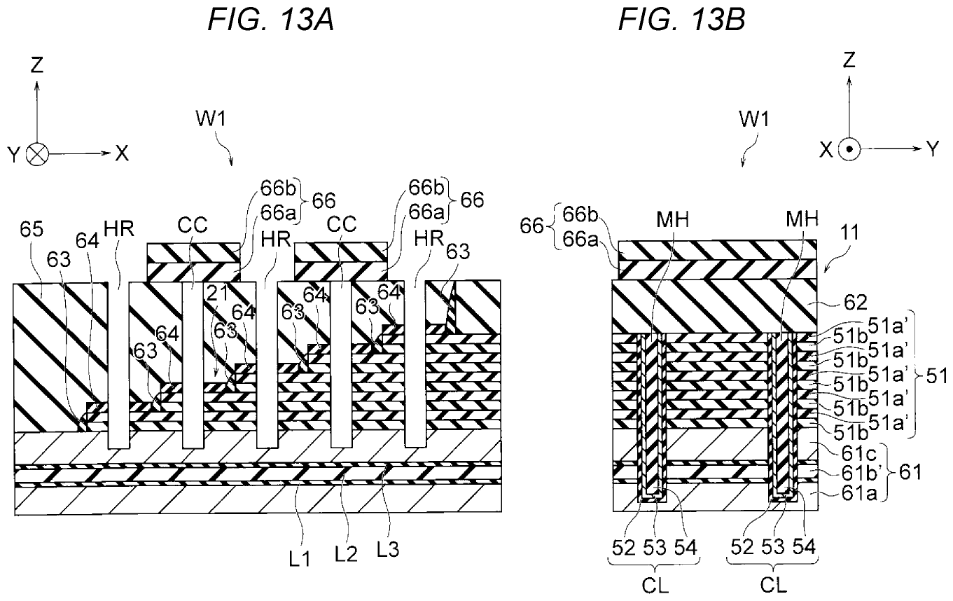

Next, a mask layer 66 is formed on the interlayer insulating films 62 and 65, and the mask layer 66 is processed into a predetermined shape (FIGS. 13A and 13B). As a result, the contact hole CC is covered with the mask layer 66, and the beam hole HR is exposed from the mask layer 66. The mask layer 66 is formed to include a lower layer 66a and an upper layer 66b in this order. The lower layer 66a is, for example, a hard mask layer. The upper layer 66b is, for example, a resist layer.

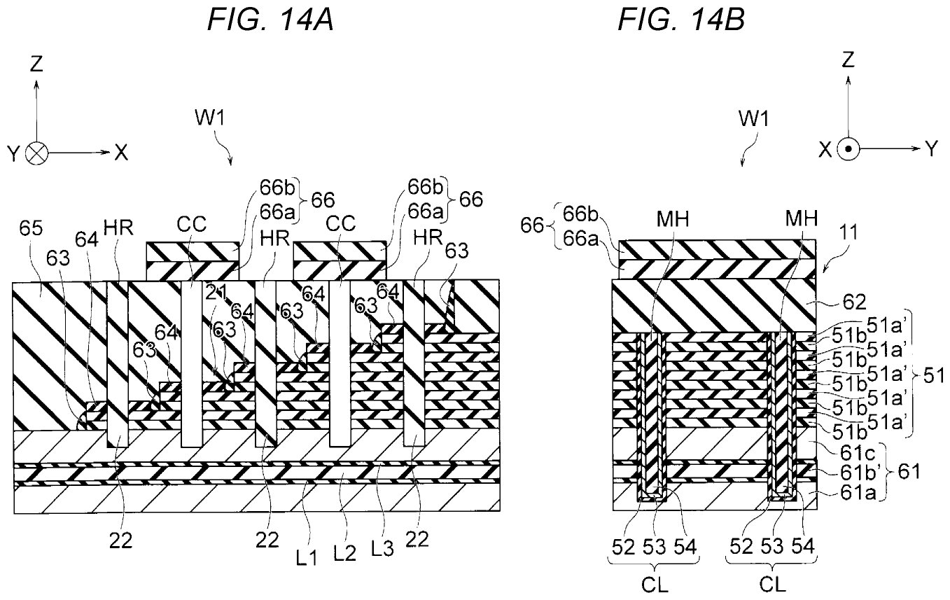

Next, a beam portion 22 is formed in each beam hole HR (FIGS. 14A and 14B). The beam portion 22 is, for example, a SiO₂ film. The beam portion 22 is formed by depositing the SiO₂ film inside and outside the beam hole HR and removing the SiO₂ film outside the beam hole HR by etching back. The beam portion 22 functions as a beam to prevent the stacked film 51 from collapsing when replacing the sacrifice layer 51a′ with the electrode 51a (replacement step) as described below. It is noted that, in the steps illustrated in FIGS. 14A and 14B, since each contact hole CC is covered with the mask layer 66, no SiO₂ film is formed in each contact hole CC.

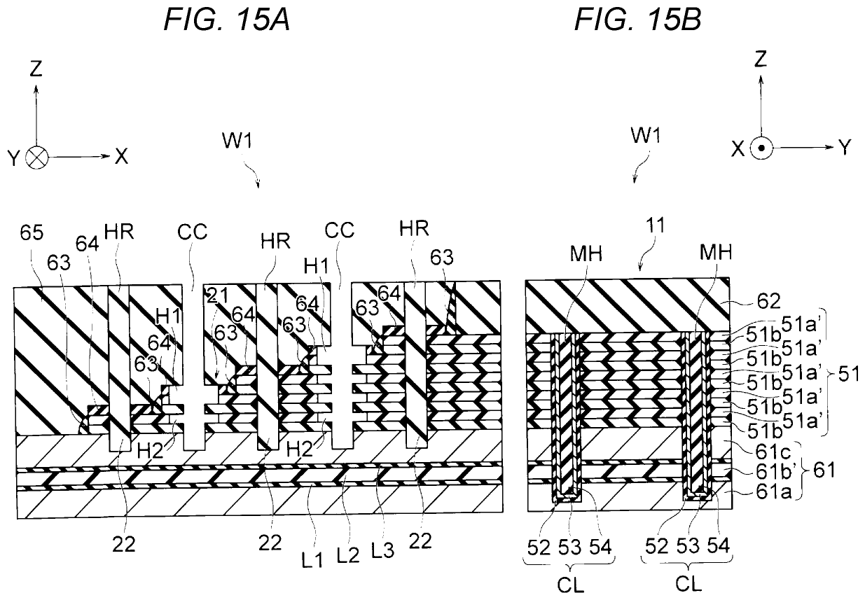

Next, the mask layer 66 is removed, and the sacrifice layer 51a′ and the selective growth layer 64 are processed from each contact hole CC by wet etching (FIGS. 15A and 15B). As a result, ring-shaped recess portions H1 and H2 are formed on the sides of each contact hole CC. Each recess portion H1 is a large recess portion formed by removing the sacrifice layer 51a′ and the selective growth layer 64. Each recess portion H2 is a small recess portion formed by removing the sacrifice layer 51a′. This wet etching performed by using, for example, H₃PO₄ (phosphoric acid).

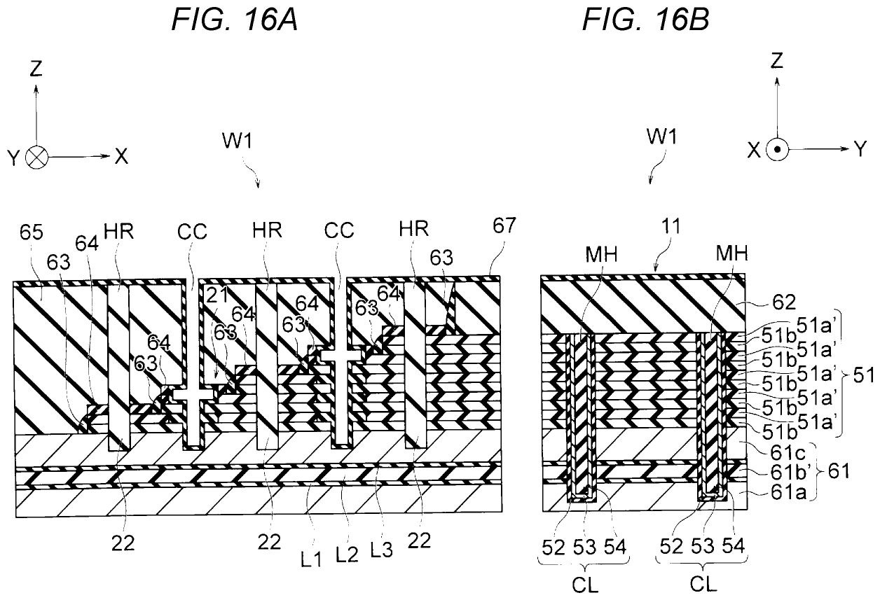

Next, an insulating film 67 is formed on the interlayer insulating films 62 and 65 (FIGS. 16A and 16B). As a result, the insulating film 67 is formed on the side and bottom surfaces of each contact hole CC. The insulating film 67 of the present embodiment is formed so that each recess portion H1 is not completely buried with the insulating film 67, and each recess portion H2 is completely buried with the insulating film 67. The insulating film 67 is, for example, a SiO₂ film. The insulating film 67 is an example of the third insulating film.

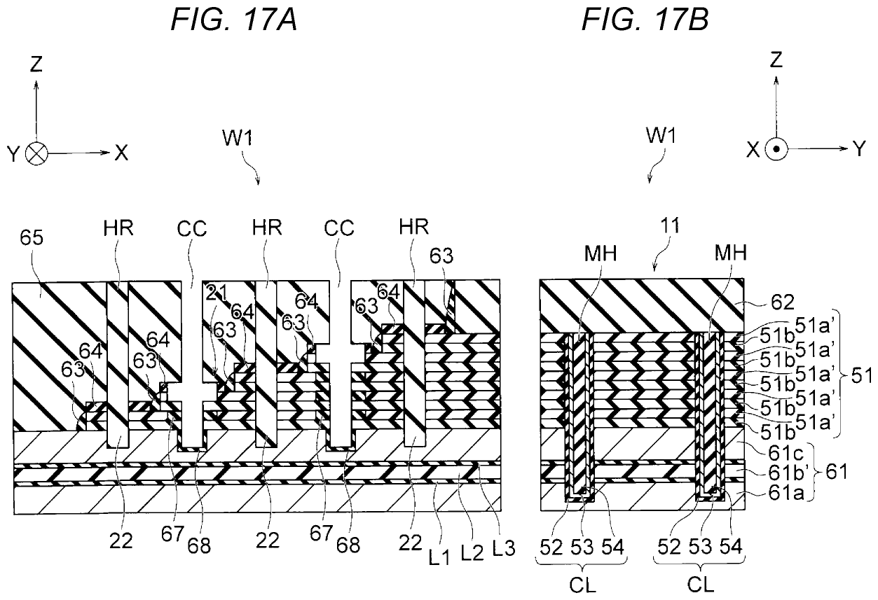

Next, the insulating film 67 is processed by chemical dry etching (CDE) (FIGS. 17A and 17B). As a result, the insulating film 67 is removed from the upper surfaces of the interlayer insulating films 62 and 65 and from each recess portion H1. Next, the upper surface of the semiconductor layer 61c is oxidized from each contact hole CC (FIGS. 17A and 17B). As a result, an insulating film 68 is formed on the upper surface of the semiconductor layer 61c exposed to each contact hole CC. The insulating film 68 is, for example, a SiO₂ film.

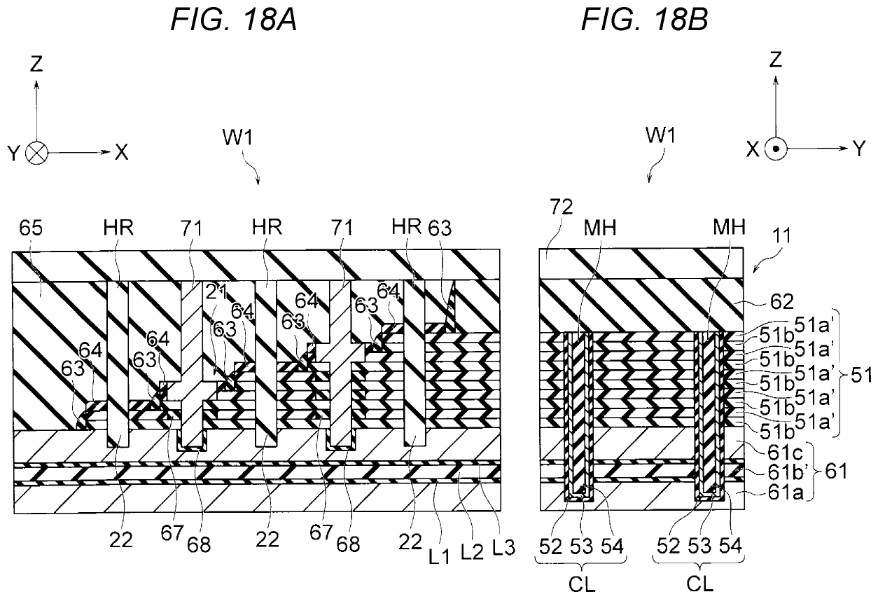

Next, a sacrifice layer 71 is formed in each contact hole CC (FIGS. 18A and 18B). The sacrifice layer 71 is further formed in the recess portion H1 on the side of each contact hole CC. The sacrifice layer 71 is, for example, an amorphous silicon (aSi) layer. The sacrifice layer 71 is formed by depositing the aSi layers inside and outside the contact hole CC and the recess portion H1 and removing the aSi layers outside the contact hole CC and the recess portion H1 by etching back. The sacrifice layer 71 is an example of the second layer. Next, an interlayer insulating film 72 is formed on the interlayer insulating films 62 and 65 (FIGS. 18A and 18B). The interlayer insulating film 72 is a portion of the interlayer insulating film 13 described above. The interlayer insulating film 72 is, for example, a SiO₂ film.

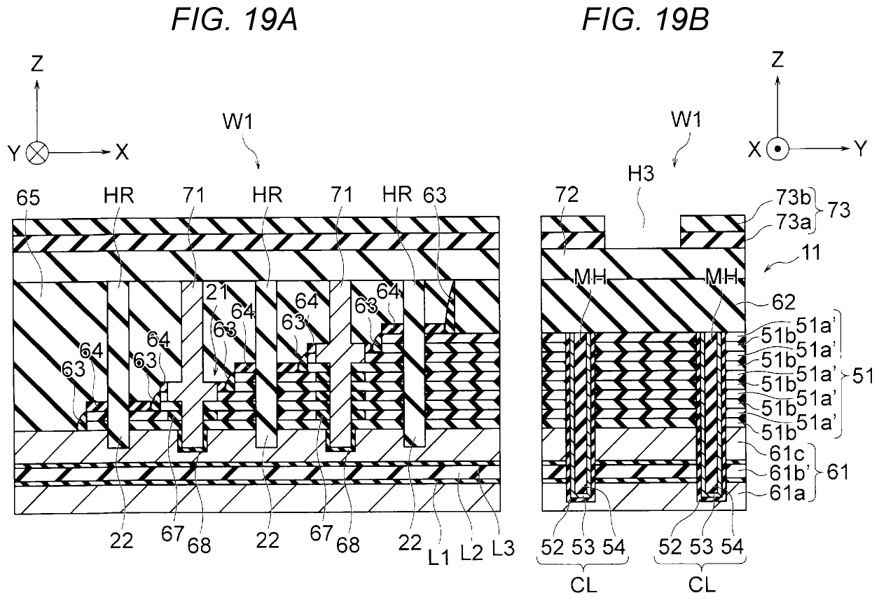

Next, a mask layer 73 is formed on the interlayer insulating film 72, and the mask layer 73 is processed into a predetermined shape (FIGS. 19A and 19B). As a result, an opening H3 is formed in the mask layer 73. The mask layer 73 is formed to include a lower layer 73a and an upper layer 73b in this order. The lower layer 73a is, for example, a hard mask layer. The upper layer 73b is, for example, a resist layer.

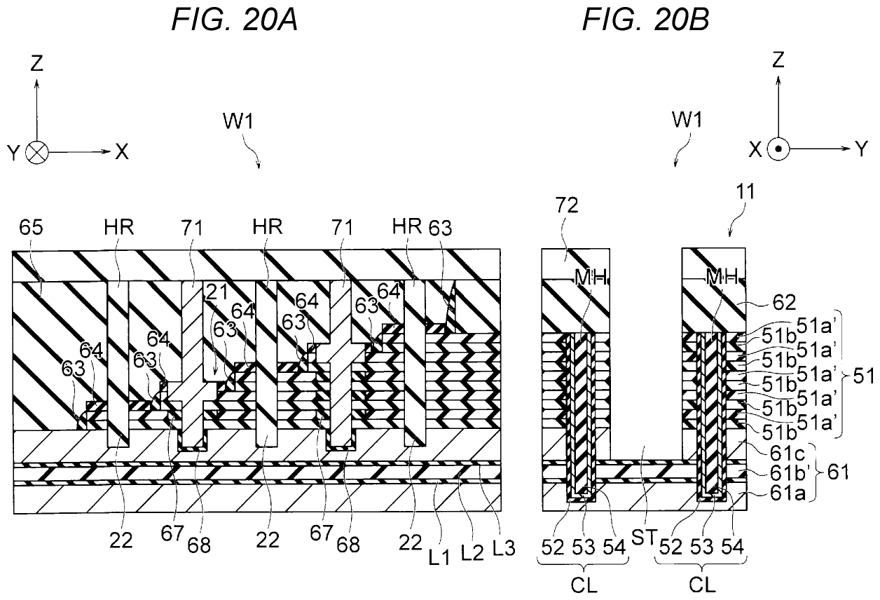

Next, by RIE using the mask layer 73, a slit ST is formed in the interlayer insulating film 72, the interlayer insulating film 62, the stacked film 51, and the semiconductor layer 61c below the opening H3 (FIGS. 20A and 20B). The slit ST is formed to extend in the Z direction and the X direction, and is formed to reach the sacrifice layer 61b′. In the present embodiment, the memory cell array 11 extends in the Y direction, and the stepped structure portion 21 extends in the X direction. Next, the mask layer 73 is removed (FIGS. 20A and 20B).

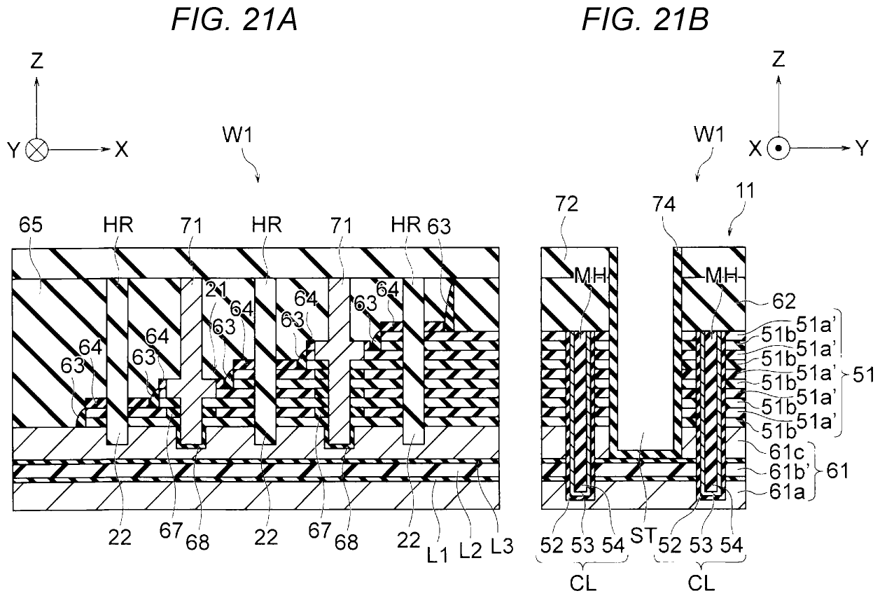

Next, the insulating film 74 is formed on the side and bottom surfaces of the slit ST (FIGS. 21A and 21B). The insulating film 74 is formed, for example, by depositing the SiN film and oxidizing the SiN film.

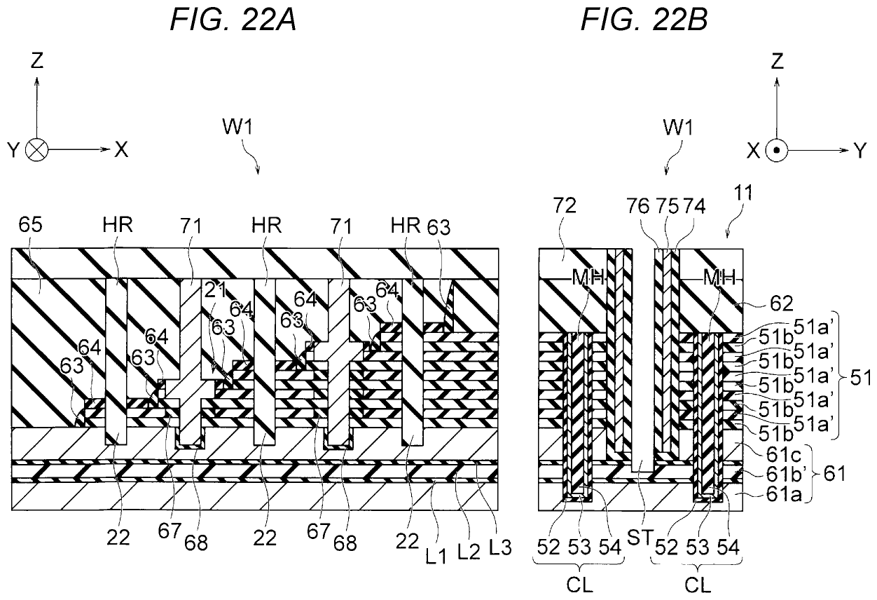

Next, the semiconductor layer 75 and the insulating film 76 are sequentially formed on the side and bottom surfaces of the slit ST via the insulating film 74, the insulating film 76, the semiconductor layer 75, and the insulating film 74 at the bottom of the slit ST are processed by lithography and RIE, and after that, the bottom of the slit ST is oxidized (FIGS. 22A and 22B). As a result, the insulating film 74, the semiconductor layer 75, and the insulating film 76 having the shapes illustrated in FIG. 22B are formed in the slit ST. The semiconductor layer 75 is, for example, an aSi layer. The insulating film 76 is, for example, a SiO₂ film.

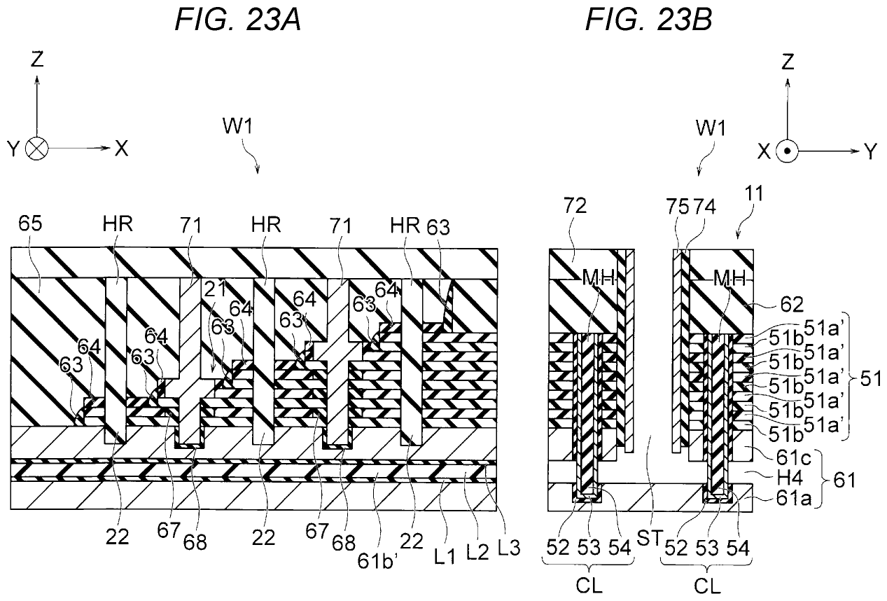

Next, the sacrifice layer 61b′ is removed from the slit ST by wet etching, and after that, a portion of the memory insulating film 52 of each columnar portion CL are removed by wet etching (FIG. 23A and FIG. 23B). As a result, a recess portion H4 is formed between the semiconductor layer 61a and the semiconductor layer 61c, and the side surface of each columnar portion CL is exposed in the recess portion H4. Furthermore, the side surface of the channel semiconductor layer 53 of each columnar portion CL is exposed in the recess portion H4. The latter wet etching is performed by using, for example, a chemical solution for removing the SiO₂ film (block insulating film 52a, tunnel insulating film 52c, and insulating film 76) and a chemical solution for removing the SiN film (charge storage layer 52b). It is noted that, in the present embodiment, the sacrifice layer 61b′ below the stepped structure portion 21 remains without being removed by these wet etchings.

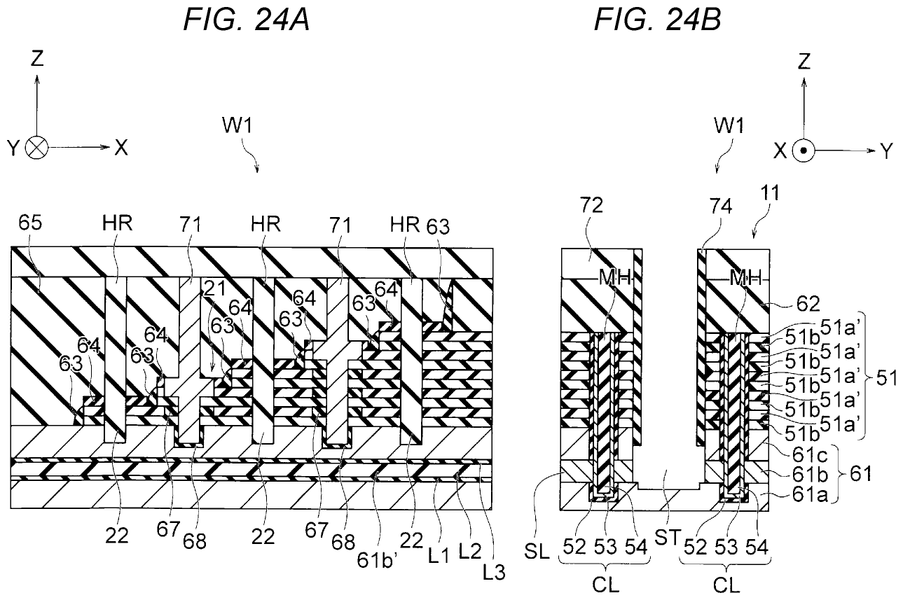

Next, the semiconductor layer 61b is formed in the recess portion H4 from the slit ST (FIGS. 24A and 24B). As a result, the source layer 61 including semiconductor layers 61a, 61b, and 61c is formed. The semiconductor layer 61b is, for example, an amorphous silicon layer. The semiconductor layer 61b is formed by depositing the amorphous silicon layer inside and outside the recess portion H4 and removing the amorphous silicon layer outside the recess portion H4 by etching back. At this time, the semiconductor layer 75 is also removed. This amorphous silicon layer contains dopants. Further, this amorphous silicon layer may be crystallized in the later step and converted into polysilicon.

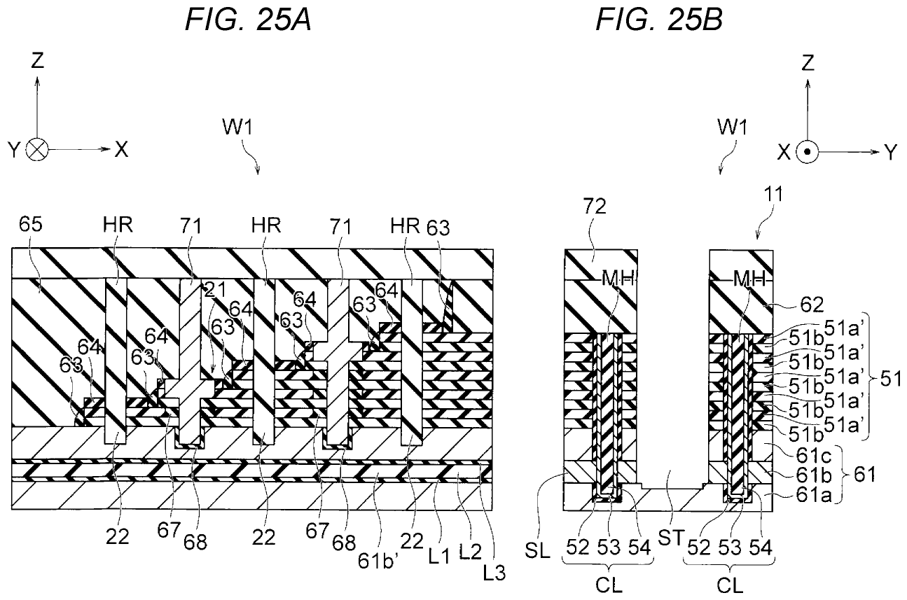

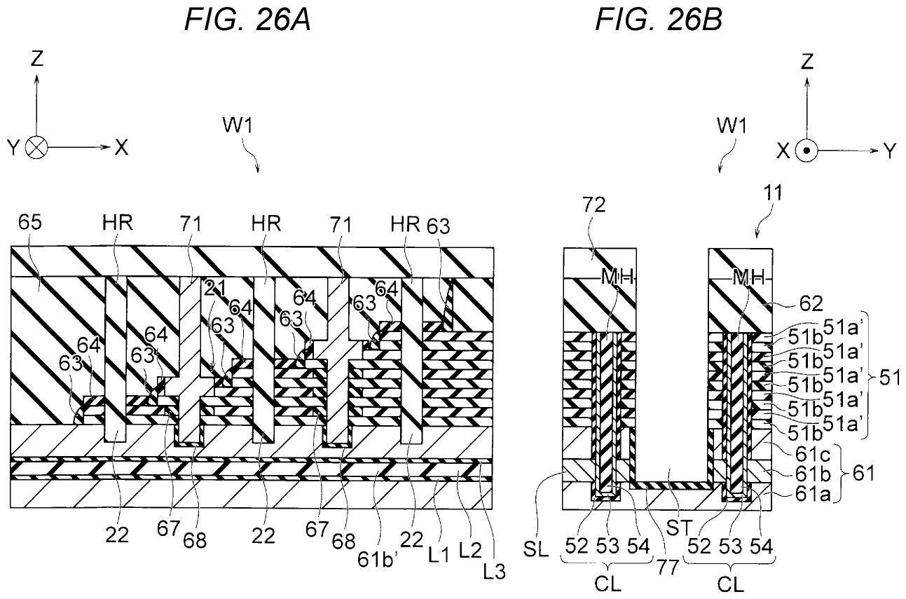

Next, the insulating film 74 is removed by the CDE (FIGS. 25A and 25B). As a result, the side surface of the stacked film 51 is exposed in the slit ST again. Next, the upper surface of the source layer 61 is oxidized from the slit ST (FIGS. 26A and 26B). As a result, the insulating film 77 is formed on the upper surface of the source layer 61 exposed in the slit ST. The insulating film 77 is, for example, a SiO₂ film.

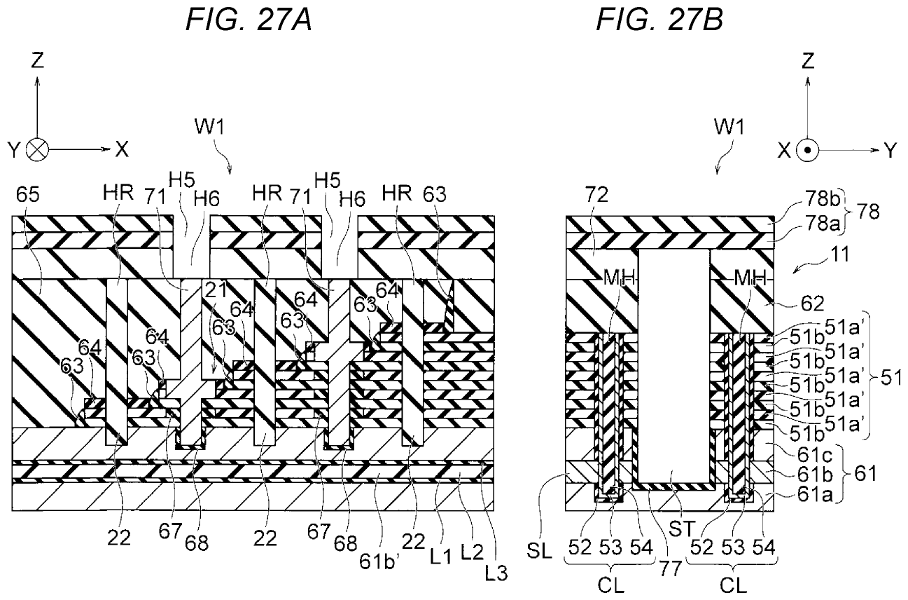

Next, the mask layer 78 is formed on the interlayer insulating film 72, and the mask layer 78 is processed into the predetermined shape (FIGS. 27A and 27B). As a result, a plurality of openings H5 are formed in the mask layer 78. The mask layer 78 is formed to include a lower layer 78a and an upper layer 78b in this order. The lower layer 78a is, for example, a hard mask layer. The upper layer 78b is, for example, a resist layer. Next, the plurality of openings H6 are formed in the interlayer insulating film 72 below the opening H5 by RIE using the mask layer 78 (FIGS. 27A and 27B).

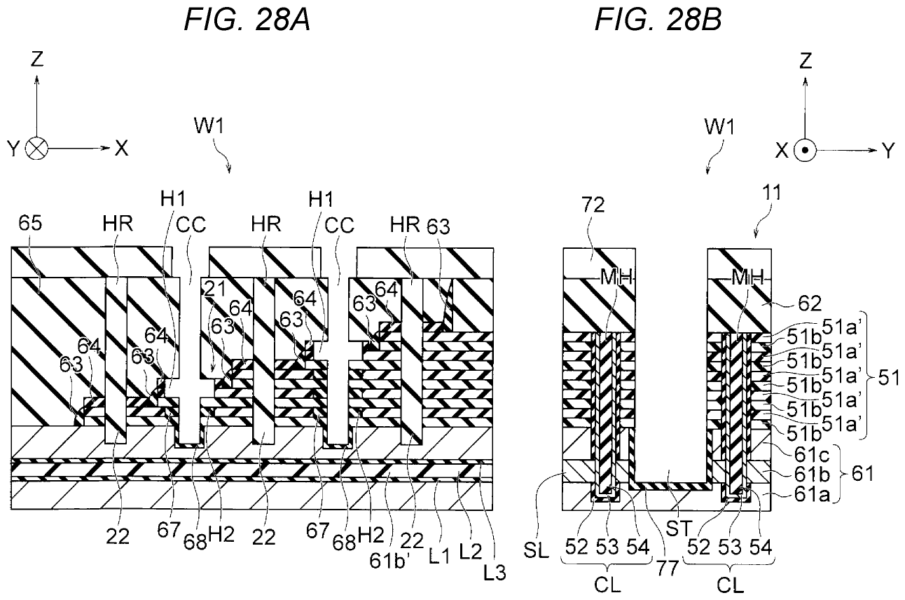

Next, the sacrifice layer 71 is removed from each contact hole CC by wet etching using the mask layer 78 (FIGS. 28A and 28B). The sacrifice layer 71 is further removed from the recess portion H1 on the side of each contact hole CC. Next, the mask layer 78 is removed (FIGS. 28A and 28B).

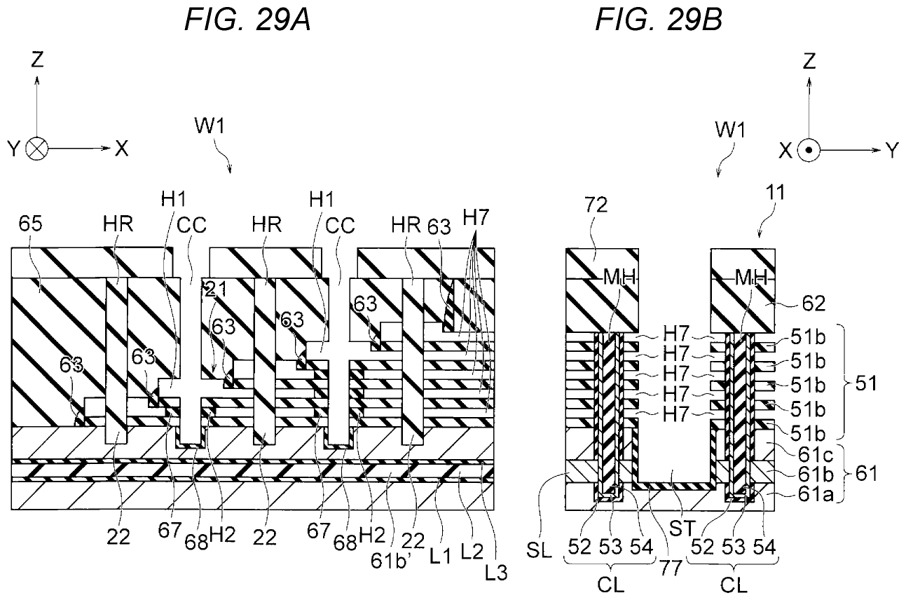

Next, the plurality of sacrifice layers 51a′ are removed from the stacked film 51 by wet etching from the slit ST and the contact hole CC (FIGS. 29A and 29B). As a result, a plurality of recess portions H7 are formed in the stacked film 51. It is noted that the wet etching illustrated in FIGS. 28A and 28B and the wet etching illustrated in FIGS. 29A and 29B are performed so that the insulating film 67 remains in each recess portion H2.

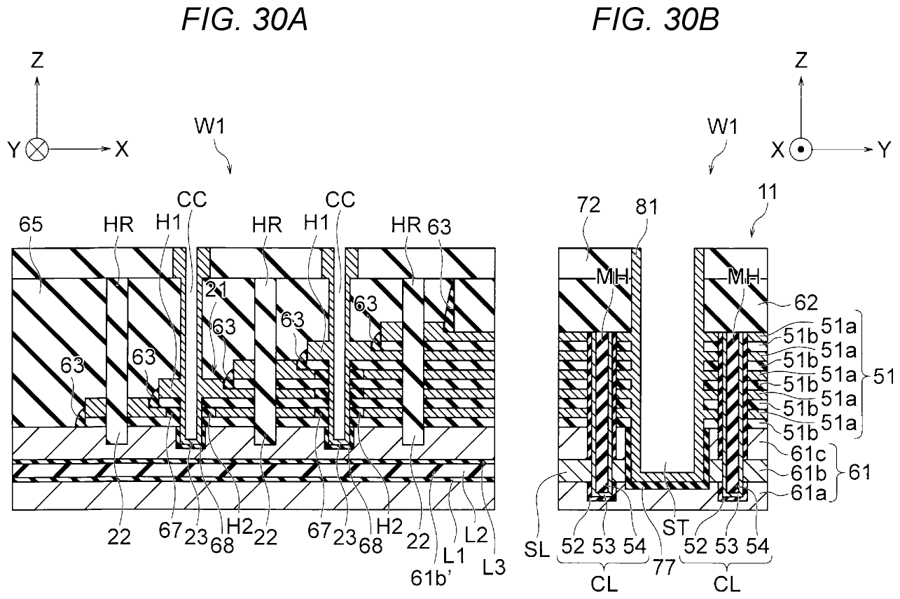

Next, the same metal layers 81 in the contact hole CC, the recess portion H1, the recess portion H7, and the slit ST are simultaneously formed (FIGS. 30A and 30B). As a result, the above-mentioned contact plug 23 is formed in each contact hole CC, and the above-mentioned electrode 51a is formed in each recess portion H7. The contact plug 23 is an example of the plug. The metal layer 81 is, for example, a stacked film including a titanium nitride film (TiN film) and the W layer. The metal layer 81 of the present embodiment is formed so that each recess portion H1 and each recess portion H7 are completely buried with the metal layer 81, and the contact hole CC and the slit ST are not completely buried with the metal layer 81. Further, as described below, the metal layer 81 of the present embodiment is formed in the contact hole CC, the recess portion H1, the recess portion H7, and the slit ST via the block insulating film (for example, an Al₂O₃ film (aluminum oxide film)). In FIGS. 30A and 30B, each contact plug 23 is provided in the stepped structure portion 21 and passes through the stacked film 51 in the Z direction.

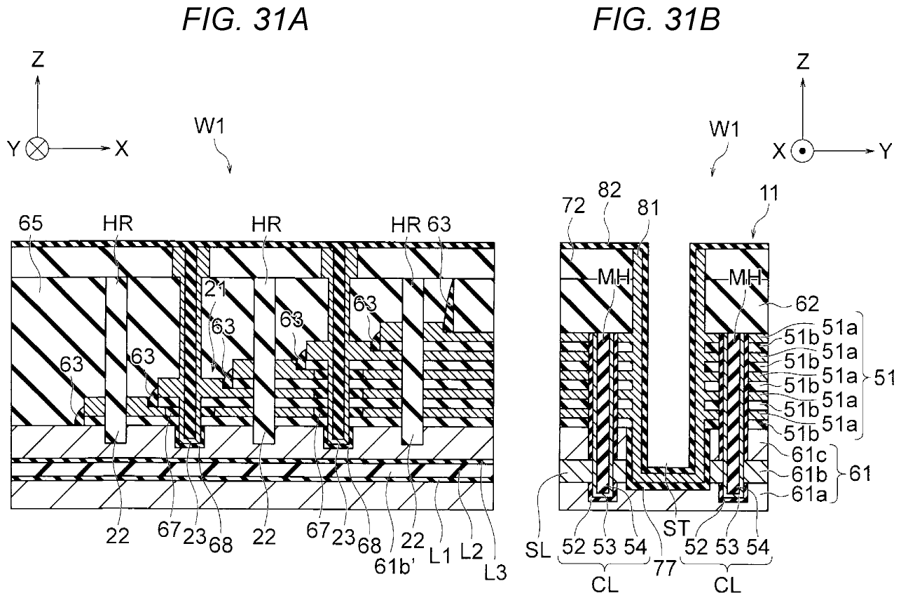

Next, an insulating film 82 is formed on the interlayer insulating film 72 (FIGS. 31A and 31B). As a result, the insulating film 82 is formed in each contact hole CC and slit ST. The insulating film 82 is, for example, a SiO₂ film. The insulating film 82 of the present embodiment is formed so that each contact hole CC is completely buried with the insulating film 82 and the slit ST is not completely buried with the insulating film 82.

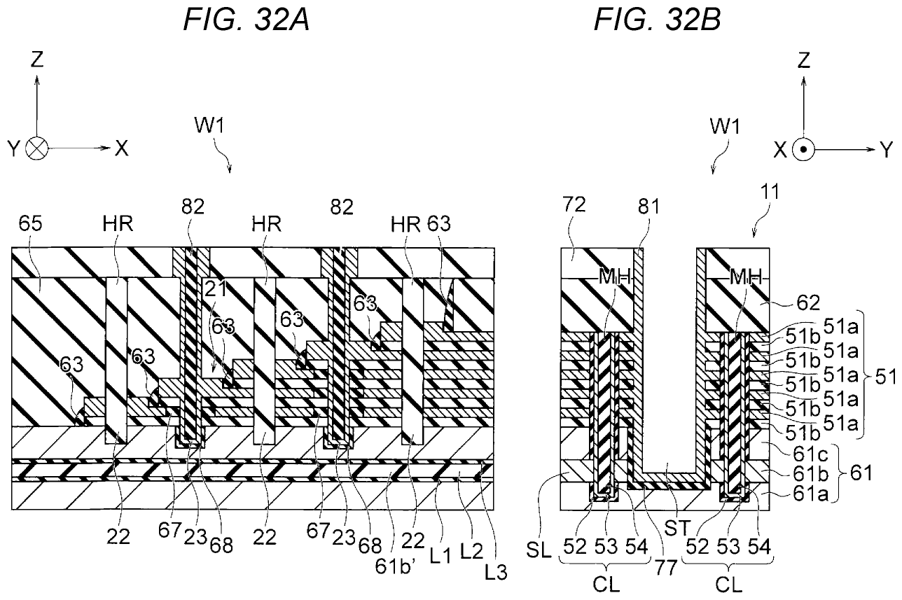

Next, the insulating film 82 is removed by etching back (FIGS. 32A and 32B). As a result, the insulating film 82 is removed from the upper surface of the interlayer insulating film 72 and the inside of the slit ST.

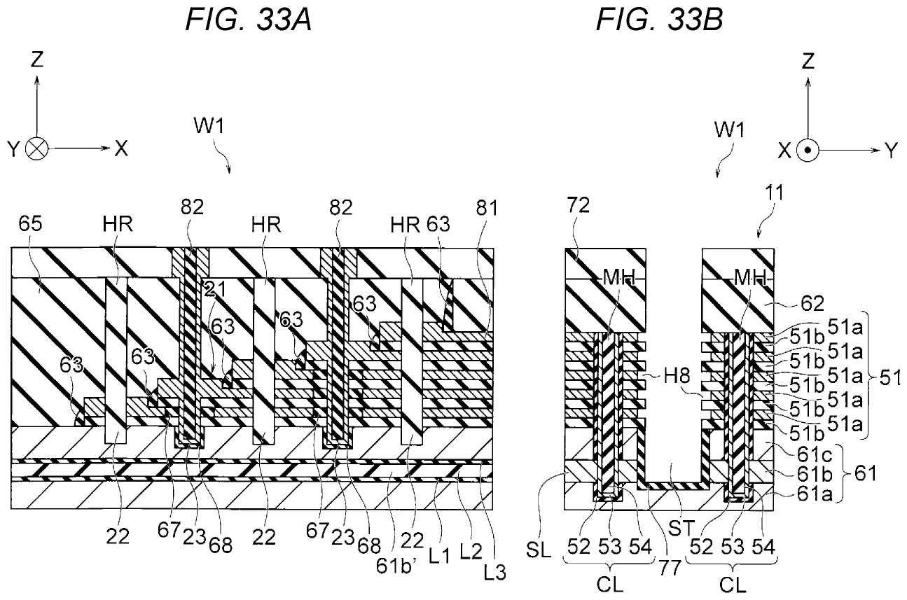

Next, the metal layer 81 in the slit ST is removed by wet etching from the slit ST (FIGS. 33A and 33B). At this time, each electrode 51a is also recessed, and a recess portion H8 is formed on the side surface of each electrode 51a.

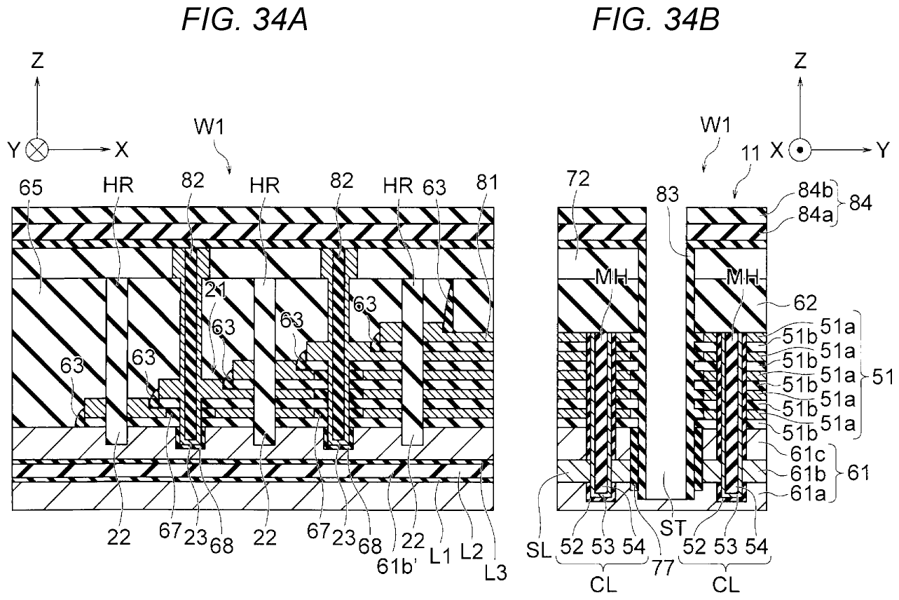

Next, an insulating film 83 is formed on the interlayer insulating film 72, and a mask layer 84 is formed on the insulating film 83 (FIGS. 34A and 34B). As a result, the insulating film 83 is formed in the slit ST, and the insulating film 83 is formed in each recess portion H8. The insulating film 83 is, for example, a SiO₂ film. The mask layer 84 is formed to include a lower layer 84a and an upper layer 84b in this order. The lower layer 84a is, for example, a hard mask layer. The upper layer 84b is, for example, a resist layer. Next, the insulating film 83 is removed from the bottom surface of the slit ST by RIE using the mask layer 84 (FIGS. 34A and 34B).

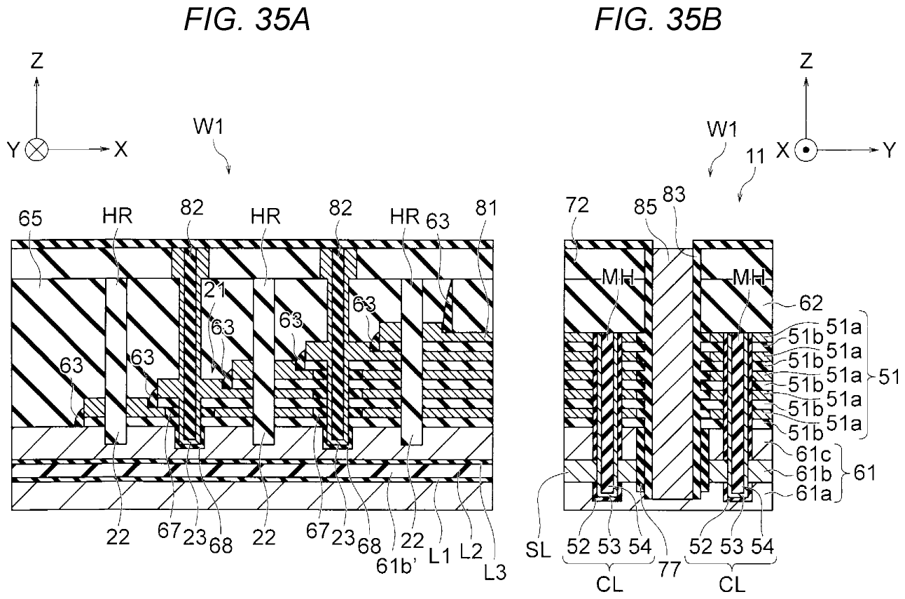

Next, a wiring layer 85 is formed on the semiconductor layer 61a in the slit ST (FIGS. 35A and 35B). The wiring layer 85 is, for example, a metal layer including the W layer. The wiring layer 85 is formed by depositing the metal layer inside and outside the slit ST and removing the metal layer outside the slit ST by the CMP.

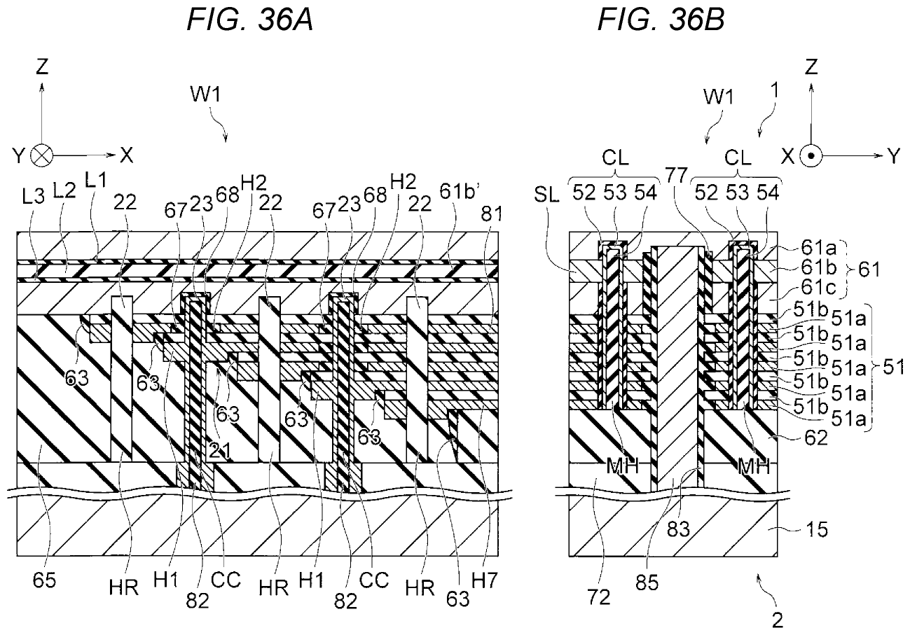

After that, as described with reference to FIG. 4, the array wafer W1 and the circuit wafer W2 are bonded together. Furthermore, the array wafer W1 and the circuit wafer W2 are cut into the plurality of chips. As a result, the semiconductor devices illustrated in FIGS. 36A and 36B are manufactured. FIGS. 36A and 36B illustrate the array chip 1 and the circuit chip 2 similarly to FIG. 1.

Hereinafter, details of the semiconductor device of the present embodiment will be described with reference to FIGS. 36A and 36B.

In FIG. 36A, each contact plug 23 is electrically connected to one electrode 51a via the metal layer 81 in the recess portion H1 and electrically connected to the other electrode 51a by the insulating film 67 or the like in the recess portion H2. Each contact plug 23 is an example of the first plug, the former electrode 51a is an example of the first electrode, and the latter electrode layer 51a is an example of a second electrode. Furthermore, the contact hole CC for each contact plug 23 is an example of the first hole, and the recess portion H7 for the former electrode 51a is an example of the first recess portion.

In this manner, each contact plug 23 illustrated in FIG. 36A is electrically connected to one electrode 51a via the metal layer 81 in the recess portion H1, and is electrically insulated from the other electrode 51a by the insulating film 67 and the like in the recess portion H2. The metal layer 81 in each contact plug 23 is not separated from the metal layer 81 in the former electrode 51a, but is continuous with (e.g., integrally formed with) the metal layer 81 in the former electrode 51a. On the other hand, the metal layer 81 in each contact plug 23 is separated from the metal layer 81 in the latter electrode 51a, and the insulating film 67 is interposed between these metal layers 81. The former electrode 51a is provided on the side surface of the metal layer 81 in the recess portion H1, and the latter electrode 51a is provided on the side surface of the insulating film 67 in the recess portion H2.

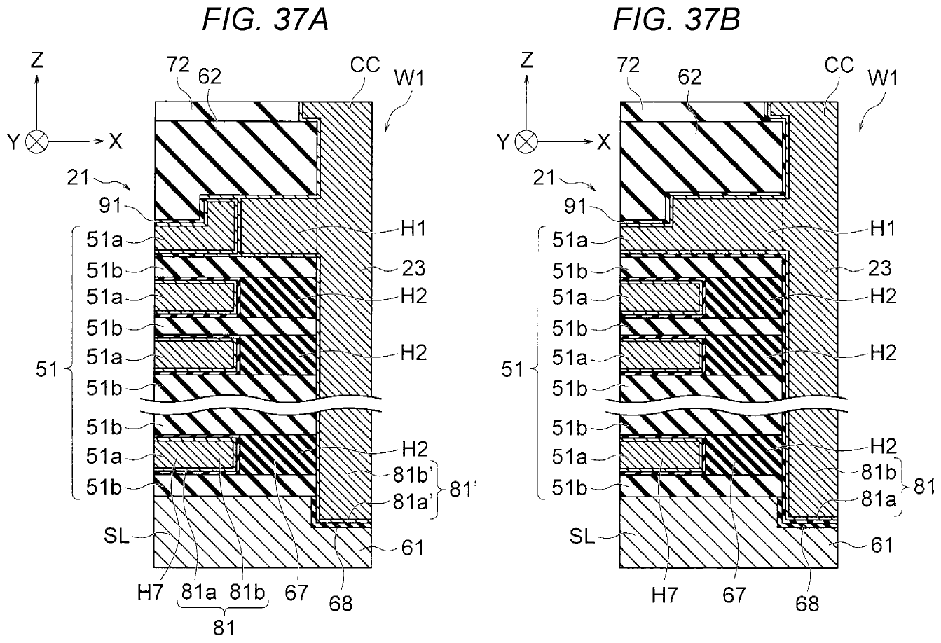

FIGS. 37A and 37B are cross-sectional view diagrams for comparing the semiconductor device of the comparative example of the first embodiment and the semiconductor device of the first embodiment.

FIG. 37A illustrates the array wafer W1 used when manufacturing the semiconductor device of the comparative example of the first embodiment. FIG. 37B illustrates the array wafer W1 used when manufacturing the semiconductor device of the first embodiment. The cross-sectional views illustrated in FIGS. 37A and 37B correspond to the cross-sectional view illustrated in FIG. 35A.

In FIGS. 37A and 37B, each electrode 51a is formed of the metal layers 81 including a barrier metal layer 81a and a fill layer 81b. Each electrode 51a is formed by sequentially forming a block insulating film 91, the barrier metal layer 81a, and the fill layer 81b in the corresponding recess portion H7. Therefore, the barrier metal layer 81a is provided on the upper surface of the fill layer 81b, and the block insulating film 91 is provided on the upper surface of the metal layer 81. The block insulating film 91 is, for example, an Al₂O₃ film. The barrier metal layer 81a is, for example, a TiN film. The fill layer 81b is, for example, a W layer. The block insulating film 91 is an example of the second insulating film, the barrier metal layer 81a is an example of the second metal layer, and the fill layer 81b is an example of the first metal layer. Further, the aluminum element contained in the block insulating film 91 is an example of the third metal element, the titanium element contained in the barrier metal layer 81a is an example of the second metal element, and the tungsten element contained in the fill layer 81b is an example of the first metal element. The block insulating film 91 is an insulating film containing the aluminum element (metal element) and the oxygen element (non-metal element).

However, the contact plug 23 illustrated in FIG. 37A is formed of metal layers 81′ different from the metal layers 81. In FIG. 37A, each recess portion H7 is buried with the barrier metal layer 81a and the fill layer 81b via the block insulating film 91, and the contact hole CC and the recess portion H1 are buried with the metal layers 81′. Therefore, at the boundary between the recess portion H1 and the recess portion H7, the side surface of the fill layer 81b is adjacent to the side surface of the metal layers 81′ via the barrier metal layer 81a. The metal layers 81′ are formed by sequentially forming a barrier metal layer 81a′ and a fill layer 81b′ in the contact hole CC and the recess portion H1. The barrier metal layer 81a′ is, for example, a TiN film. The fill layer 81b′ is, for example, a W layer.

On the other hand, the contact plug 23 illustrated in FIG. 37B is formed with the metal layers 81 as described above. In FIG. 37B, each recess portion H7 is buried with the metal layers 81 via the block insulating film 91, and the contact hole CC and the recess portion H1 are also buried with the metal layers 81 via the block insulating film 91. In FIG. 37B, the plurality of electrodes 51a and the contact plug 23 are formed by sequentially forming the block insulating film 91, the barrier metal layer 81a, and the fill layer 81b in the plurality of recess portions H7, recess portions H1, and contact holes CC. Therefore, in FIG. 37B, the block insulating film 91, barrier metal layer 81a, and fill layer 81b in the uppermost recess portion H7 are continuous with the block insulating film 91, barrier metal layer 81a, and the fill layer 81b in the recess portion H1 and contact hole CC, respectively. Further, in FIG. 37B, the fill layer 81b in the uppermost recess portion H7 is adjacent to the fill layer 81b in the recess portion H1 without the barrier metal layer 81a interposed therebetween. That is, the former fill layer 81b and the latter fill layer 81b are not separated by the barrier metal layer 81a but are continuous with each other. In addition, in FIG. 37B, since the metal layer 81′ (barrier metal layer 81a′ and fill layer 81b′) as illustrated in FIG. 37A is not formed, the fill layer 81b in the uppermost recess portion H7 is adjacent to the fill layer 81b in the recess portion H1 without either the barrier metal layer 81 or the barrier metal layer 81a′ interposed therebetween.

In FIG. 37B, the block insulating film 91 and the barrier metal layer 81a are formed not only in each recess portion H7 but also in the recess portion H1 and the contact hole CC. In FIG. 37B, the block insulating film 91 and the barrier metal layer 81a are formed on the upper and lower surfaces of each recess portion H7, on the upper and lower surfaces of recess portion H1, and on the side and bottom surfaces of the contact hole CC. Therefore, in FIG. 37B, the block insulating film 91 and the barrier metal layer 81a are formed on the upper and lower surfaces of the fill layer 81b in each recess portion H7 and recess portion H1, and are formed on the side and bottom surfaces of the fill layer 81b in the contact hole CC. The block insulating film 91 and barrier metal layer 81a of the present embodiment may also be formed at other locations in the respective recess portion H7, recess portion H1, and contact hole CC.

It is noted that the dotted lines illustrated in FIGS. 37A and 37B indicate the boundary between the contact hole CC and the recess portion H1.

Herein, the first embodiment and the comparative example will be compared.

In the comparative example, the barrier metal layer 81a is provided between the metal layer 81′ in the recess portion H1 and the fill layer 81b in the recess portion H7. Therefore, there is a concern that the electrical resistance between the metal layer 81′ in the recess portion H1 and the fill layer 81b in the recess portion H7 may increase. Further, at the boundary between the recess portion H1 and the recess portion H7 in the comparative example, in order to electrically connect the metal layer 81′ and the metal layer 81, the block insulating film 91 is removed from a region between the metal layers 81′ and the metal layers 81. In the comparative example, there is a concern that a breakdown voltage in the stacked film 51 may be reduced due to the wet etching when removing the block insulating film 91.

On the other hand, in the present embodiment, the barrier metal layer 81a is not provided between the fill layer 81b in the recess portion H1 and the fill layer 81b in the recess portion H7. Accordingly, the electrical resistance between the fill layer 81b in the recess portion H1 and the fill layer 81b in the recess portion H7 can be allowed to become lower. Further, at the boundary between the recess portion H1 and the recess portion H7 in the present embodiment, the block insulating film 91 needs not to be removed in order to electrically connect the metal layers 81 in the recess portion H1 and the metal layers 81 in the recess portion H7. Accordingly, the breakdown voltage in the stacked film 51 is prevented from decreasing due to wet etching.

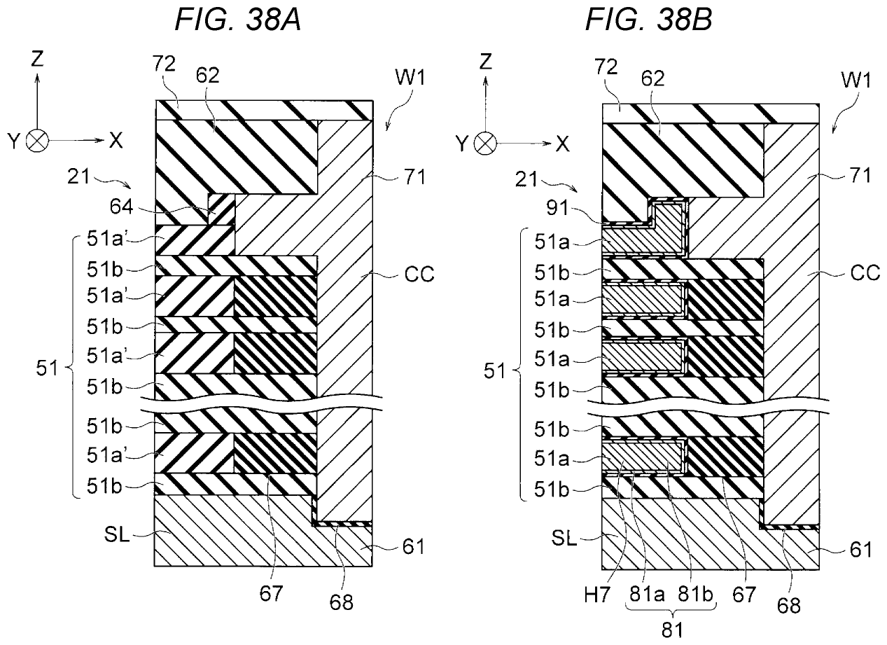

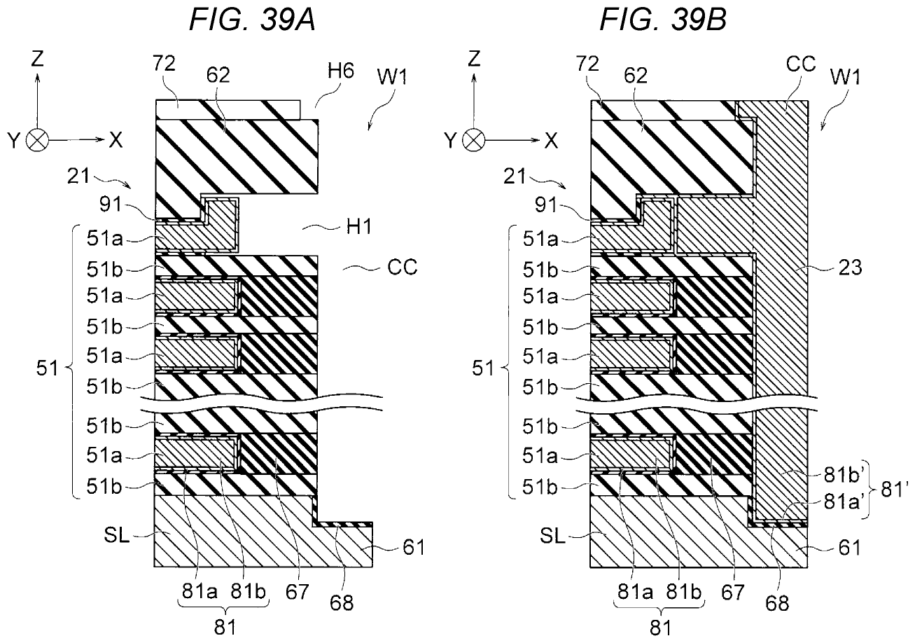

FIGS. 38 and 39 are cross-sectional view diagrams to explain process steps in the method for manufacturing the semiconductor device of the comparative example of the first embodiment.

FIG. 38A illustrates the stacked film 51 before the replacement process, and FIG. 38B illustrates the stacked film 51 after the replacement process. In the replacement step, the plurality of sacrifice layers 51a′ and the selective growth layer 64 are removed from the stacked film 51 to form the plurality of recess portions H7, and the block insulating film 91, the barrier metal layer 81a, and the fill layer 81b are sequentially formed in each recess portion H7. As a result, the plurality of electrodes 51a are formed in the stacked film 51.

Next, the sacrifice layer 71 is removed from the contact hole CC (FIG. 39A). The sacrifice layer 71 is further removed from the recess portion H1 on the side of the contact hole CC. Next, the block insulating film 91 exposed in the recess portion H1 is removed by wet etching (FIG. 39A). As a result, the barrier metal layer 81a is exposed in the recess portion H1.

Next, the metal layer 81′ is formed in the contact hole CC (FIG. 39B). As a result, the contact plug 23 is formed in the contact hole CC. The metal layers 81′ is further formed in the recess portion H1. As a result, the electrode 51a in the uppermost recess portion H7 is electrically connected to the contact plug 23 via the metal layers 81′ in the recess portion H1. The metal layers 81′ are formed by sequentially forming the barrier metal layer 81a′ and the fill layer 81b′ in the contact hole CC and the recess portion H1.

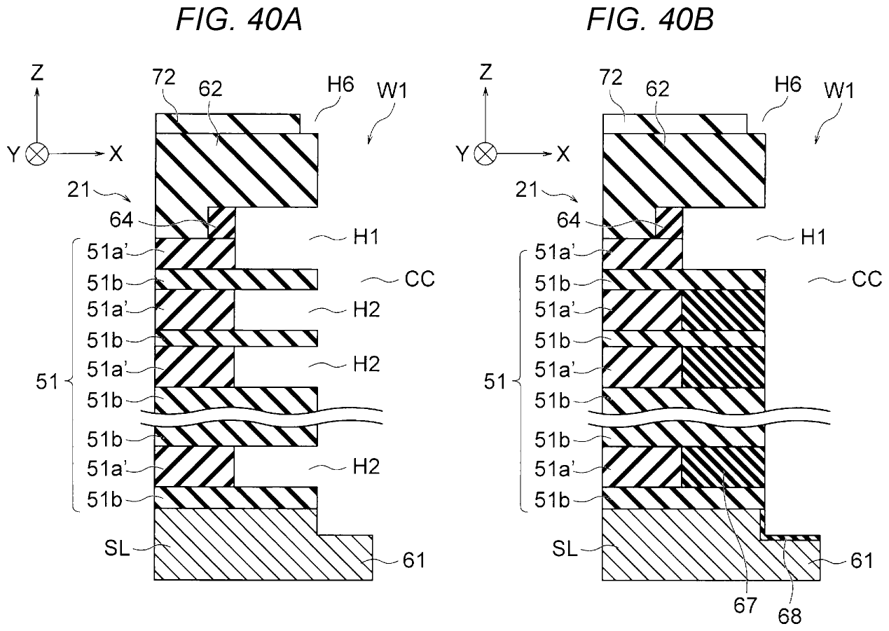

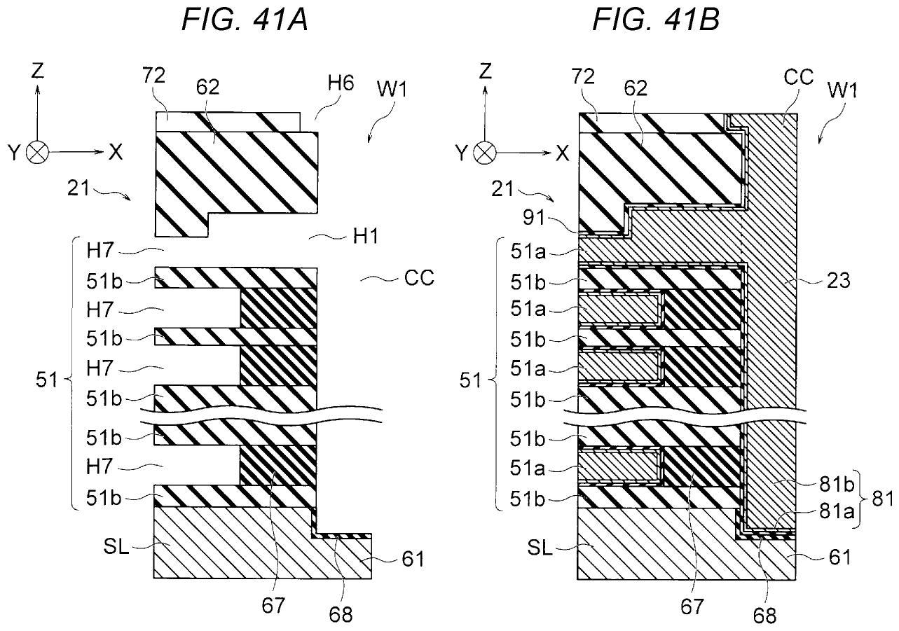

FIGS. 40 and 41 are cross-sectional view diagrams to explain process steps in the method for manufacturing the semiconductor device of the first embodiment.

FIG. 40A illustrates the recess portions H1 and H2 formed in the steps of FIGS. 15A and 15B. FIG. 40B illustrates the insulating film 67 formed in the recess portion H2 in the steps of FIGS. 16A to 17B. FIG. 41A illustrates the recess portion H7 formed in the steps of FIGS. 29A and 29B. In FIG. 41A, the recess portion H7 is formed by removing the sacrifice layer 51a′ and the selective growth layer 64 from the stacked film 51.

FIG. 41B illustrates the metal layers 81 formed in the steps of FIGS. 30A to 33B. In FIG. 41B, the block insulating film 91, the barrier metal layer 81a, and the fill layer 81b are formed sequentially in the contact hole CC, the recess portion H1, and the recess portion H7. As a result, the contact plug 23 is formed in the contact hole CC, and the electrode 51a is formed in the recess portion H7. Furthermore, the contact plug 23 is electrically connected to the corresponding electrode 51a via the metal layers 81 in the recess portion H1.

As described above, the electrode 51a and the contact plug 23 of the present embodiment are formed of the same metal layers 81. As a result, an increase in the electrical resistance between the electrode 51a and the contact plug 23 due to the barrier metal layer 81a (and the barrier metal layer 81a′) and a decrease in the breakdown voltage in the stacked film 51 due to the removal of the block insulating film 91 can be reduced. Similarly to these examples, according to the present embodiment, the suitable electrode 51a and the contact plug 23 can be implemented.

Although the contact plug 23 is formed in the stepped structure portion 21 in the stacked film 51 in the present embodiment, the contact plug 23 may be formed in other portions in the stacked film 51. Further, the block insulating film 91 may contain a metal element other than aluminum, the barrier metal layer 81a may contain a metal element other than titanium, and the fill layer 81b may contain a metal element other than tungsten. For example, the barrier metal layer 81a may contain tantalum (Ta). Further, the fill layer 81b may contain molybdenum (Mo).

While certain embodiments have been described, these embodiments have been presented by way of example only, and are not intended to limit the scope of the disclosure. Indeed, the novel embodiments described herein may be embodied in a variety of other forms; furthermore, various omissions, substitutions, and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a stacked film including a plurality of electrodes, which includes a first electrode, and a plurality of first insulating films alternately stacked in a first direction;
a plurality of plugs extending through the stacked film in the first direction, the plurality of plugs including a first plug electrically connected to the first electrode; and
a columnar portion extending through the stacked film in the first direction, the columnar portion including a charge storage layer and a semiconductor layer, wherein
the first electrode includes a metal layer and the first plug includes a metal layer that is integrally formed with the metal layer of the first electrode and formed of a same material as a material of the metal layer of the first electrode.

2. The semiconductor device according to claim 1, wherein
the metal layer of the first electrode includes a first metal layer and a second metal layer provided on at least an upper surface and a lower surface of the first metal layer, and
the metal layer of the first plug includes a third metal layer that is formed of a same material as a material of the first metal layer, and a fourth metal layer provided on at least a side surface of the third metal layer, the fourth metal layer being formed of a same material as a material of the second metal layer.

3. The semiconductor device according to claim 2, wherein the first metal layer of the first electrode is integrally formed with the third metal layer of the first plug, and the second metal layer of the first electrode is integrally formed with the fourth metal layer of the first plug.

4. The semiconductor device according to claim 2, wherein the first metal layer of the first electrode is not separated from the third metal layer of the first plug by the second and fourth metal layers.

5. The semiconductor device according to claim 2, wherein the first metal layer contains a first metal element, and the second metal layer contains a second metal element different from the first metal element.

6. The semiconductor device according to claim 5, further comprising:
a second insulating film provided on an upper surface of the first electrode and a side surface of the first plug, wherein the second insulating film contains a third metal element different from the first and second metal elements.

7. The semiconductor device according to claim 1, further comprising:
a second insulating film provided on an upper surface of the first electrode and a side surface of the first plug.

8. The semiconductor device according to claim 1, wherein the stacked film includes a stepped structure, and the first plug extends through the stepped structure of the stacked film.

9. The semiconductor device according to claim 1, wherein the plurality of electrodes includes a second electrode and the first plug is electrically insulated from the second electrode layer.

10. The semiconductor device according to claim 9, further comprising:
a third insulating film provided between the first plug and the second electrode.

11. A method for manufacturing a semiconductor device, the method comprising:
forming a stacked film including a plurality of electrodes, which includes a first electrode, and a plurality of first insulating films alternately stacked in a first direction;
forming a plurality of plugs extending through the stacked film in the first direction, the plurality of plugs including a first plug electrically connected to the first electrode; and
forming a columnar portion extending through the stacked film in the first direction, the columnar portion including a charge storage layer and a semiconductor layer, wherein
the first electrode includes a metal layer and the first plug includes a metal layer that is formed by a same process as that for the metal layer of the first electrode.

12. The method according to claim 11, wherein the metal layer of the first electrode is integrally formed with the metal layer of the first plug.

13. The method according to claim 11, wherein
the metal layer of the first electrode includes a first metal layer and a second metal layer provided on at least an upper surface and a lower surface of the first metal layer, and
the metal layer of the first plug includes a third metal layer formed by a same process as that for the first metal layer, and a fourth metal layer formed by a same process as that for the second metal layer.

14. The method according to claim 11, wherein
the first metal layer is integrally formed with the third metal layer, and
the second metal layer is integrally formed with the fourth metal layer.

15. The method according to claim 11, wherein the plurality of electrodes includes a second electrode and the first plug is formed to be electrically connected to the first electrode and electrically insulated from the second electrode.

16. A method for manufacturing a semiconductor device, comprising:
forming a stacked film including a plurality of first layers and a plurality of first insulating films stacked alternately in a first direction;
forming a columnar portion extending through the stacked film in the first direction, the columnar portion including a charge storage layer and a semiconductor layer;
forming a plurality of holes passing through the stacked film;
forming a plurality of second layers in the plurality of holes;
forming a plurality of recess portions in the stacked film by removing the plurality of second layers from the plurality of holes and removing the plurality of first layers from the stacked film;
forming a plurality of electrode, which includes a first electrode, in the plurality of recess portions; and
forming a plurality of plugs, which includes the first plug electrically connected to the first electrode, in the plurality of recess portions, wherein
the first electrode and the first plug are formed by a same process.

17. The method according to claim 16, wherein
the metal layer of the first electrode includes a first metal layer and a second metal layer provided on at least an upper surface and a lower surface of the first metal layer, and
the metal layer of the first plug includes a third metal layer formed by a same process as that for the first metal layer, and a fourth metal layer formed by a same process as that for the second metal layer.

18. The method according to claim 16, wherein the metal layer of the first electrode and the metal layer of the first plug are formed in the first hole and the first recess portion, respectively, through a second insulating film.

19. The method according to claim 16, wherein the plurality of electrodes includes a second electrode and the first plug is formed to be electrically connected to the first electrode layer and electrically insulated from the second electrode.

20. The method according to claim 19, further comprising:
before forming the plurality of second layers in the plurality of holes, forming a third insulating film from the first hole to a side surface of at least one first layer among the plurality of first layers, wherein
the plurality of recess portions are formed so that the third insulating film remains, and
the second electrode is formed on a side surface of the third insulating film.
